(19) United States
(12) Patent Application Publication
(10) Pub. No.: US 2026/0117120 A1
(43) Pub. Date: Apr. 30, 2026

(54) QUANTUM DOT, OPTICAL MEMBER INCLUDING THE QUANTUM DOT, AND ELECTRONIC APPARATUS INCLUDING THE QUANTUM DOT

(71) Applicant: Samsung Display Co., Ltd., Yongin-si (KR)

(72) Inventors: Donghee Lee, Yongin-si (KR); Jaehyun Park, Yongin-si (KR); Heewoon Im, Yongin-si (KR)

(73) Assignee: Samsung Display Co., Ltd., Yongin-si (KR)

(21) Appl. No.: 19/284,865

(22) Filed: Jul. 30, 2025

(30) Foreign Application Priority Data
Oct. 29, 2024 (FR) 10-2024-0149767

(51) Int. Cl. C09K 11/62; B82Y 20/00; B82Y 40/00; H10K 59/38

(52) U.S. Cl. CPC C09K 11/623; H10K 59/38; B82Y 20/00; B82Y 40/00

(57) ABSTRACT

Embodiments provide a quantum dot, an optical member including the quantum dot, an electronic apparatus including the quantum dot, and electronic equipment including the electronic apparatus. The quantum dot includes: a core that includes a Group I element, a Group III element, a Group VI element, and gallium (Ga); a first shell covering the core, wherein the first shell includes a Group I element, a Group III element, a Group VI element, and gallium (Ga); and a second shell covering the first shell. Band gap energies of the core, the first shell, and the second shell satisfy Expressions 1 and 2, which are explained in the specification:

$${EB}_{SHELL 1} < {EB}_{CORE} \qquad [ Expression 1 ]$$

$${EB}_{CORE} < {EB}_{SHELL 2} . \qquad [ Expression 2 ]$$

### CROSS-REFERENCE TO RELATED APPLICATION(S)

This application claims priority to and benefits of Korean Patent Application No. 10-2024-0149767 under 35 USC § 119, filed on Oct. 29, 2024, in the Korean Intellectual Property Office, the entire contents of which are incorporated herein by reference.

### BACKGROUND

### 1. Technical Field

Embodiments relate to a quantum dot, an optical member including the quantum dot, and an electronic apparatus including the quantum dot.

### 2. Description of the Related Art

Quantum dots are nano-sized semiconductor nanocrystals that exhibit a quantum confinement effect. By controlling the size, composition, and the like of nanocrystals, the nanocrystals may have different energy band gaps and thus may emit light with various emission wavelengths.

These quantum dots may be variously used in optical members and various electronic apparatuses. There is a need for quantum dots with a narrow full width at half maximum and excellent quantum efficiency at a desired wavelength.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a quantum dot having a narrow full width at half maximum and excellent quantum efficiency.

Additional aspects will be set forth in part in the description which follows and, in part, will be apparent from the description, or may be learned by practice of the embodiments of the disclosure.

According to embodiments,
a quantum dot may include a core that may include:
a Group I element, a Group III element, a Group VI element, and gallium (Ga);
a first shell covering the core, the first shell may include a Group I element, a Group III element, a Group VI element, and gallium (Ga); and
a second shell covering the first shell, wherein
band gap energies of the core, the first shell, and the second shell may satisfy Expressions 1 and 2:

$${EB}_{SHELL 1} < {EB}_{CORE} \qquad [ Expression 1 ]$$

$${EB}_{CORE} < {EB}_{SHELL 2} \qquad [ Expression 2 ]$$

In Expressions 1 and 2,
EB_{CORE} is a band gap energy of the core,
EB_{SHELL1} is a band gap energy of the first shell, and
EB_{SHELL2} is a band gap energy of the second shell.

In an embodiment, the Group I element of the core and the Group I element of the first shell may each independently be copper (Cu), silver (Ag), gold (Au), or any combination thereof.

In an embodiment, the Group I element of the core may be different from the Group I element of the first shell.

In an embodiment, the Group III element of the core and the Group III element of the first shell may each independently be aluminum (Al), indium (In), thallium (Tl), or any combination thereof.

In an embodiment, the Group VI element of the core and the Group VI element of the shell may each independently be sulfur (S), selenium (Se), tellurium (Te), or any combination thereof.

In an embodiment, the core may include at least one of Ag, In, Ga, and S.

In an embodiment, the first shell may include at least one of Cu, In, Ga, and S.

In an embodiment, the core may have a composition of AgInₓGa₁₋ₓS, provided that 0<x<1, and the first shell may have a composition of CuIn_{y}Ga_{1-y}S, provided that 0<x<1.

In an embodiment, the quantum dot may satisfy one of Conditions 1 to 7:

### [Condition 1]

when the core has a composition of AgInₓGa₁₋ₓS, provided that 0<x≤0.2, the first shell has a composition of CuIn_{y}Ga_{1-y}S, provided that 0<y<1;

### [Condition 2]

when the core has a composition of AgInₓGa₁₋ₓS, provided that 0.2<x≤0.3, the first shell has a composition of CuIn_{y}Ga_{1-y}S, provided that 0.1≤y<1;

### [Condition 3]

when the core has a composition of AgInₓGa₁₋ₓS, provided that 0.3<x≤0.4, the first shell has a composition of CuIn_{y}Ga_{1-y}S, provided that 0.2≤y<1;

### [Condition 4]

when the core has a composition of AgInₓGa₁₋ₓS, provided that 0.4<x≤0.6, the first shell has a composition of CuIn_{y}Ga_{1-y}S, provided that 0.3≤y<1;

### [Condition 5]

when the core has a composition of AgInₓGa₁₋ₓS, provided that 0.6<x≤0.7, the first shell has a composition of CuIn_{y}Ga_{1-y}S, provided that 0.4≤y<1;

### [Condition 6]

when the core has a composition of AgInₓGa₁₋ₓS, provided that 0.7<x≤0.8, the first shell has a composition of CuIn_{y}Ga_{1-y}S, provided that 0.5≤y<1; or

### [Condition 7]

when the core has a composition of AgInₓGa₁₋ₓS, provided that 0.8<x≤1, the first shell has a composition of CuIn_{y}Ga_{1-y}S, provided that 0.6≤y<1.

In an embodiment, the second shell may include a Group II-VI compound, a Group III-VI compound, or any combination thereof.

In an embodiment, the second shell may include ZnS, ZnSe, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

In an embodiment, in the quantum dot, a full width at half maximum of a photoluminescence (PL) spectrum may be less than or equal to about 60 nm for incident light having a wavelength of 450 nm.

In an embodiment, a diameter of the core may be in a range of about 2 nm to about 8 nm.

In an embodiment, a thickness of the first shell may be in a range of about 1 nm to about 2 nm; and a thickness of the second shell may be in a range of about 0.3 nm to about 2 nm.

In an embodiment, a surface of the quantum dot may include an organic ligand or a metal halide.

According to embodiments, an optical member may include the quantum dot.

According to embodiments, an electronic apparatus may include the quantum dot.

In an embodiment, the electronic apparatus may further include a light source, and a color conversion member disposed on a path of light emitted from the light source, wherein the color conversion member may include the quantum dot.

According to embodiments, an electronic equipment may include the electronic apparatus.

In an embodiment, the electronic equipment may be a flat panel display, a curved display, a computer monitor, a medical monitor, a television, a billboard, an indoor light, an outdoor light, a signaling light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro-display, a three-dimensional (3D) display, a virtual or augmented reality display, a vehicle, a video wall with multiple displays tiled together, a theater screen, a stadium screen, a phototherapy device, or a signboard.

In an embodiment, the electronic apparatus may be a display apparatus.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic cross-sectional view of a quantum dot according to an embodiment;

FIG. 2 is a graph of band gap energies of a core, a first shell, and a second shell of a quantum dot according to an embodiment;

FIG. 3 is a schematic cross-sectional view of a light-emitting device according to an embodiment;

FIG. 4 is a schematic cross-sectional view of an electronic apparatus according to another embodiment;

FIG. 5 is a schematic perspective view of an electronic equipment including a light-emitting device according to an embodiment;

FIG. 6 is a schematic view of an exterior of a vehicle as an electronic equipment including a light-emitting device according to an embodiment;

FIGS. 7A to 7C are each a schematic diagram of an interior of a vehicle according to embodiments;

FIG. 8 is a graph showing photoluminescence (PL) spectra of quantum dots prepared in Comparative Test Example 1 and Comparative Test Example 2;

FIG. 9 is a graph showing PL spectra of quantum dots prepared in Comparative Test Example 3, Test Example 1, and Test Example 2; and

FIG. 10 is a graph showing a quantum yield (QY) retention rate according to a light exposure time of quantum dots of Comparative Test Examples 1 to 3, Test Example 1, and Test Example 2.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on”, “directly connected to”, or “directly coupled to” another element, there are no intervening elements present. For example, “directly on” may mean that two layers or two elements are disposed without an additional element such as an adhesion element therebetween.

In the specification, the expressions used in the singular such as “a”, “an”, and “the” are intended to include the plural forms as well, unless the context clearly indicates otherwise.

In the specification, the term “and/or” includes any and all combinations of one or more of the associated listed items. For example, “A and/or B” may be understood to mean “A, B, or A and B”. The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of”, modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises”, “comprising”, “includes”, “including”, “have”, “having”, “contains”, “containing”, and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “Group I” may encompass Group IA elements and Group IB elements in the IUPAC Periodic Table of the Elements. Examples of Group I elements may include silver (Ag), copper (Cu), and the like.

In the specification, the term “Group II” may encompass Group IIA elements and Group IIB elements of the IUPAC Periodic Table of the Elements. Examples of Group II elements may include magnesium (Mg), calcium (Ca), zinc (Zn), cadmium (Cd), mercury (Hg), and the like.

In the specification, the term “Group III” may encompass Group IIIA elements and Group IIIB elements in the IUPAC Periodic Table of the Elements. Examples of Group III elements may include aluminum (Al), gallium (Ga), indium (In), thallium (Tl), and the like.

In the specification, the term “Group VI” may encompass Group VIA elements and Group VIB elements qin the IUPAC Periodic Table. Examples of Group VI elements may include oxygen (O), sulfur (S), selenium (Se), tellurium (Te), and the like.

### [Quantum Dot]

A quantum dot according to an embodiment may include: a core including a Group I element, a Group III element, a Group VI element, and gallium (Ga); a first shell covering the core, the first shell including a Group I element, a Group III element, a Group VI element, and gallium (Ga); and a second shell covering the first shell.

Band gap energies of the core, the first shell, and the second shell may satisfy Expressions 1 and 2:

$${EB}_{SHELL 1} < {EB}_{CORE} \qquad [ Expression 1 ]$$

$${EB}_{CORE} < {EB}_{SHELL 2} \qquad [ Expression 2 ]$$

In Expressions 1 and 2,
EB_{CORE} may be a band gap energy of the core,
EB_{SHELL1} may be a band gap energy of the first shell, and
EB_{SHELL2} may be a band gap energy of the second shell.

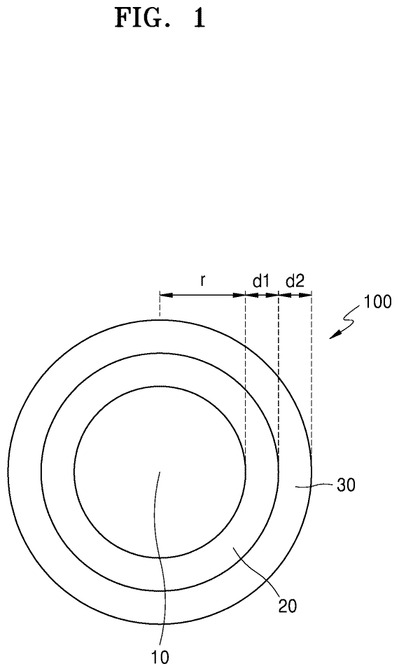

FIG. 1 is a schematic cross-sectional view of a quantum dot 100 according to an embodiment. The quantum dot 100 may include a core 10, a first shell 20 surrounding the core 10, and a second shell 30 surrounding the first shell 20.

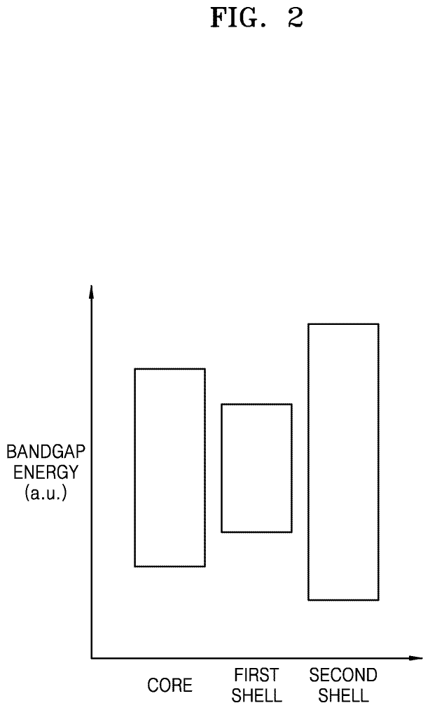

FIG. 2 is a graph of band gap energies of the core 10, the first shell 20, and the second shell 30 of the quantum dot 100. In FIG. 2, a length of each bar represents a magnitude of band gap energy. Referring to FIG. 2, the band gap energy of the first shell 20 positioned between the core 10 and the second shell 30 may be less than each of the band gap energies of the core 10 and the second shell 30. The band gap energies of the core 10, the first shell 20, and the second shell 30 may satisfy Expressions 1 and 2. The first shell 20 having a band gap energy that is less than a band gap energy of each of the core 10 and the second shell 30 may be introduced between the core 10 and the second shell 30, thereby improving quantum efficiency and durability, as represented by a quantum efficiency retention rate. It may be estimated that the introduction of the first shell 20 having a low energy level increases an electron distribution probability in a bulk of the quantum dot 100 so that a coupling between a quantum dot surface and a bulk (surface-bulk coupling) may be reduced, and durability against surface damage may be improved. The coupling between the quantum dot surface and the bulk means that surface damage and an electron exchange may directly affect the bulk.

In an embodiment, a Group I element of a core and a Group 1 element of a first shell may each independently be copper (Cu), silver (Ag), gold (Au), or any combination thereof. In an embodiment, the Group I element of the core may be different from the Group I element of the first shell. For example, the Group I element of the core may be silver (Ag), and the Group I element of the first shell may be copper (Cu). In an embodiment, the Group I element of the core may be identical to the Group I element of the first shell. For example, the Group I elements of the core and the first shell may both be silver (Ag) or copper (Cu).

In an embodiment, a Group III element of the core and a Group III element of the first shell may each independently be aluminum (Al), indium (In), thallium (Tl), or any combination thereof. In an embodiment, the Group III element of the core may be identical to the Group III element of the first shell. For example, the Group III elements of the core and the first shell may both be indium (In).

In an embodiment, a Group VI element of the core and a Group VI element of the first shell may each independently be sulfur (S), selenium (Se), tellurium (Te), or any combination thereof. In an embodiment, the Group VI element of the core may be identical to the Group VI element of the first shell. For example, the Group VI elements of the core and the first shell may both be sulfur (S). In an embodiment, the Group VI element of the core may be different from the Group VI element of the first shell.

In an embodiment, excluding the Group I elements, the Group III element and the Group VI element of the core may be identical to the Group III element and the Group VI element of the first shell. For example, the core may include at least one of Ag, In, Ga, and S; and the first shell may include at least one of Cu, In, Ga, and S.

In an embodiment, all components of the core and all components of the first shell may be identical to each other. For example, the core and the first shell may both include at least one of Ag, In, Ga, and S. For example, the core and the first shell may both include at least one of Cu, In, Ga, and S.

In the specification, the use of parenthetical mathematical expressions indicates that x or y have a value within the recited range.

In an embodiment, the core may have a composition of AgInₓGa₁₋ₓS (0<x<1), and the first shell may have a composition of CuIn_{y}Ga_{1-y}S (0<y<1).

Table 1 shows band gap energies according to a composition ratio of In to Ga in compounds of AgInₓGa₁₋ₓS (0≤x≤1) and CuIn_{y}Ga_{1-y}S (0≤y≤1).

TABLE 1

| | Band gap | First shell | Band gap |
|---|---|---|---|
| Core composition | energy (eV) | composition | energy (eV) |
| AgInS | 1.9 | CuInS | 1.5 |
| AgIn_{0.9}Ga_{0.1}S | 1.98 | CuIn_{0.9}Ga_{0.1}S | 1.6 |
| AgIn_{0.8}Ga_{0.2}S | 2.06 | CuIn_{0.8}Ga_{0.2}S | 1.7 |
| AgIn_{0.7}Ga_{0.3}S | 2.14 | CuIn_{0.7}Ga_{0.3}S | 1.8 |
| AgIn_{0.6}Ga_{0.4}S | 2.22 | CuIn_{0.6}Ga_{0.4}S | 1.9 |
| AgIn_{0.5}Ga_{0.5}S | 2.3 | CuIn_{0.5}Ga_{0.5}S | 2.0 |
| AgIn_{0.4}Ga_{0.6}S | 2.38 | CuIn_{0.4}Ga_{0.6}S | 2.1 |
| AgIn_{0.3}Ga_{0.7}S | 2.46 | CuIn_{0.3}Ga_{0.7}S | 2.2 |
| AgIn_{0.2}Ga_{0.8}S | 2.54 | CuIn_{0.2}Ga_{0.8}S | 2.3 |
| AgIn_{0.1}Ga_{0.9}S | 2.62 | CuIn_{0.1}Ga_{0.9}S | 2.4 |
| AgGaS | 2.7 | CuGaS | 2.5 |

Band gap energies of the compounds are calculated by predicting the contribution according to a content of each of In and Ga through linear interpolation from band gap energy literature values (AgInS 1.9 eV, AgGaS 2.7 eV, CuInS 1.5 eV, and CuGaS 2.5 eV) (source: Ternary Quantum Dots: Synthesis, Properties, and Applications (Woodhead Publishing Series in Electronic and Optical Materials, 2021)). Referring to Table 1, it is shown that the band gap energy increases as the ratio of In to Ga decreases in the compounds of AgInₓGa₁₋ₓS (0≤x≤1) and CuIn_{y}Ga_{1-y}S.

In an embodiment, the core of the quantum dot may have a composition of AgInₓGa₁₋ₓS (0<x<1), the first shell of the quantum dot may have a composition of CuIn_{y}Ga_{1-y}S (0<y<1), and the quantum dot may satisfy one of Conditions 1 to 7:

### [Condition 1]

when the core has a composition of AgInₓGa₁₋ₓS (0<x≤0.2), the first shell has a composition of CuIn_{y}Ga_{1-y}S (0<y<1);

### [Condition 2]

when the core has a composition of AgInₓGa₁₋ₓS (0.2<x≤0.3), the first shell has a composition of CuIn_{y}Ga_{1-y}S (0.1≤y<1);

### [Condition 3]

when the core has a composition of AgInₓGa₁₋ₓS (0.3<x≤0.4), the first shell has a composition of CuIn_{y}Ga_{1-y}S (0.2≤y<1);

### [Condition 4]

when the core has a composition of AgInₓGa₁₋ₓS (0.4<x≤0.6), the first shell has a composition of CuIn_{y}Ga_{1-y}S (0.3≤y<1);

### [Condition 5]

when the core has a composition of AgInₓGa₁₋ₓS (0.6<x≤0.7), the first shell has a composition of CuIn_{y}Ga_{1-y}S (0.4≤y<1);

### [Condition 6]

when the core has a composition of AgInₓGa₁₋ₓS (0.7<x≤0.8), the first shell has a composition of CuIn_{y}Ga_{1-y}S (0.5≤y<1); or

### [Condition 7]

when the core has a composition of AgInₓGa₁₋ₓS (0.8<x≤1), the first shell has a composition of CuIn_{y}Ga_{1-y}S (0.6≤y<1).

In an embodiment, considering band gap energies of AgInₓGa₁₋ₓS (0≤x≤1) and CuIn_{y}Ga_{1-y}S (0≤y≤1) shown in Table 1, Conditions 1 to 7 may be conditions in which compositions satisfy Expressions 1 and 2.

For example, in Condition 1, when the core has a composition of AgInₓGa₁₋ₓS (0<x≤0.2), band gap energy EB_{CORE} of the core may satisfy a range of 2.54≤EB_{CORE}<2.7, and when the first shell has a composition of CuIn_{y}Ga_{1-y}S (0<y<1), band gap energy EB_{SHELL1} of the first shell may satisfy a range of 1.5≤EB_{SHELL1}<2.5. Therefore, a condition of EB_{SHELL1}<EB_{CORE} may be satisfied.

For example, in Condition 2, when the core has a composition of AgInₓGa₁₋ₓS (0.2<x≤0.3), the band gap energy EB_{CORE} of the core may satisfy a range of 2.46≤EB_{CORE}<2.54, and when the first shell has a composition of CuIn_{y}Ga_{1-y}S (0.1≤y<1), the band gap energy EB_{SHELL1} of the first shell may satisfy a range of 1.5≤EB_{SHELL1}<2.5. Therefore, a condition of EB_{SHELL1}<EB_{CORE} may be satisfied.

For example, in Condition 3, when the core has a composition of AgInₓGa₁₋ₓS (0.3<x≤0.4), the band gap energy EB_{CORE} of the core may satisfy a range of 2.38≤EB_{CORE}<2.46, and when the first shell has a composition of CuIn_{y}Ga_{1-y}S (0.2≤y<1), the band gap energy EB_{SHELL1} of the first shell may satisfy a range of 1.5≤EB_{SHELL1}<2.3. Therefore, a condition of EB_{SHELL1}<EB_{CORE} may be satisfied.

For example, in Condition 4, when the core has a composition of AgInₓGa₁₋ₓS (0.4<x≤0.6), the band gap energy EB_{CORE} of the core may satisfy a range of 2.22≤EB_{CORE}<2.38, and when the first shell has a composition of CuIn_{y}Ga_{1-y}S (0.3≤y<1), the band gap energy EB_{SHELL1} of the first shell may satisfy a range of 1.5≤EB_{SHELL1}<2.2. Therefore, a condition of EB_{SHELL1}<EB_{CORE} may be satisfied.

For example, in Condition 5, when the core has a composition of AgInₓGa₁₋ₓS (0.6<x≤0.7), the band gap energy EB_{CORE} of the core may satisfy a range of 2.14≤EB_{CORE}<2.22, and when the first shell has a composition of CuIn_{y}Ga_{1-y}S (0.4≤y<1), the band gap energy EB_{SHELL1} of the first shell may satisfy a range of 1.5≤EB_{SHELL1}<2.1. Therefore, a condition of EB_{SHELL1}<EB_{CORE} may be satisfied.

For example, in Condition 6, when the core has a composition of AgInₓGa₁₋ₓS (0.7<x≤0.8), the band gap energy EB_{CORE} of the core may satisfy a range of 2.06≤EB_{CORE}<2.14, and when the first shell has a composition of CuIn_{y}Ga_{1-y}S (0.5≤y<1), the band gap energy EB_{SHELL1} of the first shell may satisfy a range of 1.5≤EB_{SHELL1}<2.0. Therefore, a condition of EB_{SHELL1}<EB_{CORE} may be satisfied.

For example, in Condition 7, when the core has a composition of AgInₓGa₁₋ₓS (0.8<x<1), the band gap energy EB_{CORE} of the core may satisfy a range of 1.9≤EB_{CORE}<2.06, and when the first shell has a composition of CuIn_{y}Ga_{1-y}S (0.6≤y<1), the band gap energy EB_{SHELL1} of the first shell may satisfy a range of 1.5≤EB_{SHELL1}<1.9. Therefore, a condition of EB_{SHELL1}<EB_{CORE} may be satisfied.

In an embodiment, a second shell may include a Group II-VI compound, a Group III-VI compound, or any combination thereof. For example, the second shell may include ZnS, ZnSe, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

In an embodiment, in the quantum dot, a full width at half maximum of a photoluminescence (PL) spectrum may be less than or equal to about 60 nm for incident light having a wavelength of 450 nm.

In an embodiment, a diameter 2r (see FIG. 1) of the core may be in a range of about 2 nm to about 8 nm.

In an embodiment, a thickness d1 (see FIG. 1) of the first shell may be in a range of about 1 nm to about 2 nm.

In an embodiment, a thickness d2 (see FIG. 1) of the second shell may be in a range of about 0.3 nm to about 2 nm.

In an embodiment, a surface of the quantum dot may include an organic ligand or a metal halide. The organic ligand may include, for example, a C₄-C₃₀ fatty acid such as a palmitic acid, a stearic acid, or an oleic acid, an amine having a C₄-C₃₀ hydrocarbon chain, such as oleylamine (OLA) or trioctylamine, or a thiol having a C₄-C₃₀ hydrocarbon chain, such as dodecanethiol. The metal halide may be derived from a metal precursor during quantum dot synthesis and may include, for example, CuI, AgI, InI, or GaI.

According to an embodiment, the quantum dot may be in the form of a spherical particle, a pyramidal particle, a multi-arm particle, a cubic nanoparticle, a nanotube particle, a nanowire particle, a nanofiber particle, or a nanoplate particle.

In an embodiment, the quantum dot may be spherical.

In an embodiment, a maximum emission wavelength of a photoluminescence (PL) spectrum of the quantum dot may be in a range of about 500 nm to about 650 nm. For example, a maximum emission wavelength of a PL spectrum of the quantum dot may be in a range of about 510 nm to about 550 nm. For example, a maximum emission wavelength of a PL spectrum of the quantum dot may be in a range of about 600 nm to about 650 nm. For example, a maximum emission wavelength of a PL spectrum of the quantum dot may be in a range of about 610 nm to about 640 nm.

According to an embodiment, PL quantum efficiency of the quantum dot may be in a range of about 60% to about 98%. For example, PL quantum efficiency of the quantum dot may be in a range of about 80% to about 97%. For example, PL quantum efficiency of the quantum dot may be in a range of about 85% to about 95%. For example, PL quantum efficiency of the quantum dot may be in a range of about 88% to about 95%.

According to an embodiment, the quantum dot may have a full width at half maximum (FWHM) of an emission wavelength spectrum in a range of about 30 nm to about 60 nm. Color purity or color reproducibility may be improved within such a range. Light emitted through the quantum dot may be emitted in all directions, which may improve a wide viewing angle.

In the quantum dot according to embodiments, the first shell, which includes a Group I element, a Group III element, a Group VI element, and gallium (Ga) like the core and may have a band gap energy less than that of the core, may be provided between the core and the second shell, thereby improving lattice constant matching with the core to improve quantum efficiency and a FWHM. In an embodiment, the first shell having a higher melting point and binding force than the core may be introduced to form a robust multi-shell structure, thereby improving the reliability of a quantum dot.

The quantum dot may be synthesized through a wet chemical process, an organic metal chemical vapor deposition process, a molecular beam epitaxy process, or any similar process.

The wet chemical process may be a method that mixes an organic solvent and a precursor material and growing crystals of quantum dot particles. When the crystals grow, since an organic solvent spontaneously serves as a dispersant coordinated to a surface of a quantum dot crystal and controls the growth of the crystals, the growth of quantum dot particles may be controlled through a process that costs less and may be more readily performed as compared to vapor deposition such as metal organic chemical vapor deposition (MOCVD) or molecular beam epitaxy (MBE).

An energy band gap may be controlled by controlling a size of the quantum dot, and thus light with various wavelengths may be obtained in a quantum dot emission layer. Therefore, by using quantum dots with different sizes, a light-emitting device that emits light with different wavelengths may be implemented. For example, the size of the quantum dot may be selected to emit red light, green light, and/or blue light. In an embodiment, the quantum dot may have a size such that light of various colors are combined to emit white light.

### [Ink Composition]

According to an embodiment, an ink composition may include the quantum dot and a solvent.

According to an embodiment, a content of the quantum dot may be in a range of about 1.0 parts by weight to about 10 parts by weight with respect to a total of 100 parts by weight of the ink composition. For example, the content of the quantum dot may be in a range of about 2 parts by weight to about 5 parts by weight with respect to a total of 100 parts by weight of the ink composition.

According to an embodiment, a content of the solvent may be in a range of about 80 parts by weight to about 99.9 parts by weight with respect to a total of 100 parts by weight of the ink composition. For example, the content of the solvent may be in a range of about 90 parts by weight to about 99.8 parts by weight with respect to a total of 100 parts by weight of the ink composition.

According to an embodiment, the ink composition may have a viscosity in a range of about 2 cP to about 10 cP.

According to an embodiment, the ink composition may have a surface tension in a range of about 20 dyne/cm to about 40 dyne/cm.

According to an embodiment, a vapor pressure of the ink composition may be less than or equal to about 10⁻² mmHg.

Since the ink composition has the above range of viscosity, the above range of surface tension, and the above range of vapor pressure, an inkjet process of discharging the ink composition may be readily performed.

According to an embodiment, the solvent may be a hydrophilic or hydrophobic solvent.

According to an embodiment, the hydrophobic solvent may include at least one of an aliphatic hydrocarbon-based solvent and an aromatic hydrocarbon-based solvent.

For example, the hydrophobic solvent may include at least one of: alkanes including n-pentane, n-hexane, n-heptane, n-octane, n-nonane, n-decane, dodecane, hexadecane, and oxadecane; haloalkanes including dichloromethane, 1,2-dichloroethane, and 1,1,2-trichloroethane; cycloalkanes including cyclohexane and methylcyclohexane; aryls including toluene, xylene, mesitylene, ethylbenzene, n-hexylbenzene, octylbenzene, cyclohexylbenzene, trimethylbenzene, and tetrahydronaphthalene; and haloaryls including chlorobenzene, o-dichlorobenzene, and cyclohexylbenzene.

In an embodiment, the hydrophilic solvent may include at least of an alcohol group, an ether group, a ketone group, and an ester group.

For example, the hydrophilic solvent may include at least one of: alkylene glycol alkyl ethers such as ethylene glycol monomethyl ether, ethylene glycol monoethyl ether, ethylene glycol monopropyl ether, ethylene glycol monobutyl ether, propylene glycol monomethyl ether, and propylene glycol methyl ethyl ether; diethylene glycol dialkyl ethers such as diethylene glycol dimethyl ether, diethylene glycol diethyl ether, diethylene glycol dipropyl ether, and diethylene glycol dibutyl ether; alkylene glycol alkyl ether acetates such as methyl cellosolve acetate, ethyl cellosolve acetate, propylene glycol monomethyl ether acetate, propylene glycol monoethyl ether acetate, and propylene glycol monopropyl ether acetate; alkoxyalkyl acetates such as methoxybutyl acetate and methoxypentyl acetate; aromatic hydrocarbons such as benzene, toluene, xylene, and mesitylene; ketones such as methyl ethyl ketone, acetone, methyl amyl ketone, methyl isobutyl ketone, and cyclohexanone; alcohols such as ethanol, propanol, butanol, hexanol, cyclohexanol, ethylene glycol, and glycerin; esters such as ethoxypropionic acid ethyl ester, 3-methoxypropionic acid methyl ester, and 3-phenyl-propionic acid ethyl ester; and methoxybenzene (anisole).

The ink composition including the quantum dot and the solvent according to the embodiments may have excellent emission properties and quantum efficiency, and thus an optical member, an electronic apparatus, and electronic equipment which have high quality may be provided using the ink composition.

### [Light-Emitting Device]

The quantum dot as described herein may be used as an emitter of a light-emitting device. Therefore, according to an embodiment, in a light-emitting device including a first electrode, a second electrode facing the first electrode, and an emission layer disposed between the first electrode and the second electrode, the quantum dot may be included in an emission layer. The light-emitting device may further include a hole transport region disposed between the first electrode and the emission layer, an electron transport region disposed between the emission layer and the second electrode, or any combination thereof.

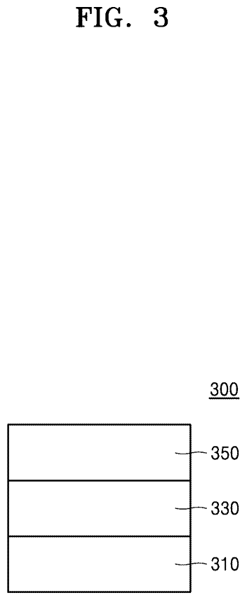

### [Description of FIG. 3]

FIG. 3 is a schematic cross-sectional view of a light-emitting device 300 according to an embodiment.

The light-emitting device 300 may include a first electrode 310, a second electrode 350 facing the first electrode 310; and an interlayer 330 disposed between the first electrode 310 and the second electrode 350 and including an emission layer. The emission layer may include the quantum dot according to embodiments. Hereinafter, each layer of the light-emitting device 300 will be described.

### [First Electrode 310]

A substrate may be further included below the first electrode 310 or on the second electrode 350 of FIG. 3. In an embodiment, the substrate may be a glass substrate or a plastic substrate that has excellent mechanical strength, thermal stability, transparency, surface smoothness, ease of handling, and is waterproof.

For example, when the light-emitting device 300 is a top emission type in which light is emitted in a direction opposite to the substrate, the substrate does not necessarily need to be transparent and may be opaque or translucent. In an embodiment, the substrate may be formed of metal. When the substrate is formed of metal, the substrate may also include carbon, iron, chromium, manganese, nickel, titanium, molybdenum, stainless steel (SUS), an Invar™ alloy, an Inconel™ alloy, a Kovar™ alloy, or any combination thereof.

Although not shown in FIG. 3, a buffer layer, a thin film transistor, an organic insulating layer, or the like may be further included between the substrate and the first electrode 310.

The first electrode 310 may be formed, for example, by providing a first electrode material onto the substrate by using deposition or sputtering. The first electrode 310 may be a reflective electrode, a semi-transmissive electrode, or a transmissive electrode. When the first electrode 310 is a transparent electrode, the first electrode material may include indium tin oxide (ITO), indium zinc oxide (IZO), tin oxide (SnO₂), zinc oxide (ZnO), gallium zinc oxide (GZO), aluminum zinc oxide (AZO), InZnSnOx (IZTO), ZnSnOx (ZTO), graphene, poly(3,4-ethylenedioxythiophene)/poly(4-styrenesulfonate) (PEDOT/PSS), carbon nanotubes, silver nanowires (Ag nanowires), gold nanowires (Au nanowires), metal meshes, or any combination thereof. When the first electrode 310 is a semi-transmissive electrode or a reflective electrode, the first electrode material may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 310 may have a structure consisting of a single layer or a structure including multiple layers. For example, the first electrode 310 may have a three-layered structure of ITO/Ag/ITO.

### [Interlayer 330]

The interlayer 330 may be disposed on the first electrode 310. The interlayer 330 may include the emission layer.

The interlayer 330 may further include a hole transport region disposed between the first electrode 310 and the emission layer and an electron transport region disposed between the emission layer and the second electrode 350.

In addition to various organic materials, the interlayer 330 may further include a metal-containing compound such as an organometallic compound and an inorganic material such as a quantum dot.

In an embodiment, the interlayer 330 may include two or more light-emitting units stacked between the first electrode 310 and the second electrode 350, and at least one charge generation layer disposed between adjacent units among the two or more light-emitting units. When the interlayer 330 includes the two or more light-emitting units and the at least one charge generation layer as described above, the light-emitting device 300 may be a tandem light-emitting device.

### [Hole Transport Region in Interlayer 330]

The hole transport region may have a structure consisting of a single material, a structure consisting of a layer including different materials, or a structure including multiple layers including different materials.

The hole transport region may include a hole injection layer, a hole transport layer, an emission auxiliary layer, an electron blocking layer, or any combination thereof.

For example, the hole transport region may have a structure which consists of a layer including different materials or the hole transport region may have a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked from the first electrode 310 in its respective stated order, but the structure of the hole transport region is not limited thereto.

The hole transport region may include an amorphous inorganic or organic material. The inorganic material may include NiO, MoO₃, Cr₂O₃, or Bi₂O₃. In an embodiment, the inorganic material may include: a p-type inorganic semiconductor such as a p-type inorganic semiconductor in which an iodide, bromide, or chloride of Cu, Ag, or Au is doped with a non-metal such as O, S, Se, or Te; a p-type inorganic semiconductor in which a compound containing Zn is doped with a metal such as Cu, Ag, or Au or with a non-metal such as N, P, As, Sb, or Bi; or a voluntary p-type inorganic semiconductor such as ZnTe.

In embodiments, the organic material may include a compound represented by Formula 201, a compound represented by Formula 202, or any combination thereof:

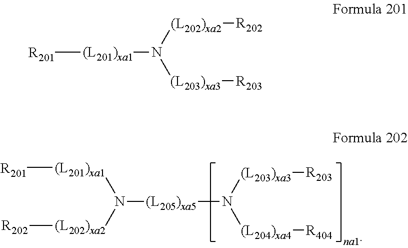

In Formula 201 and Formula 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other through a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (for example, a carbazole group) unsubstituted or substituted with at least one R₁₀ₐ (for example, see Compound HT16 or the like),
R₂₀₃ and R₂₀₄ may optionally be linked to each other through a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulas CY201 to CY217:

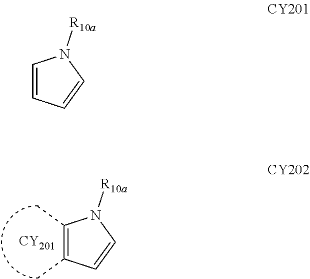

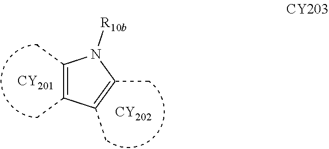

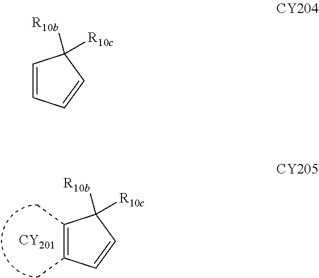

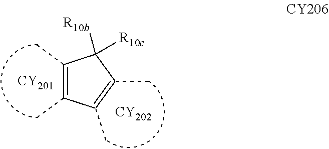

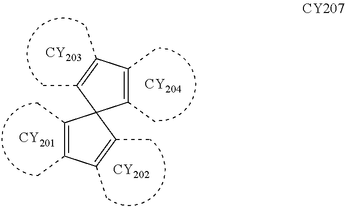

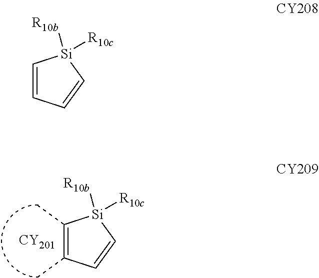

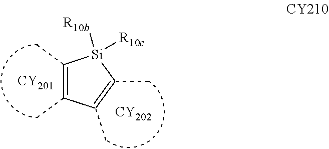

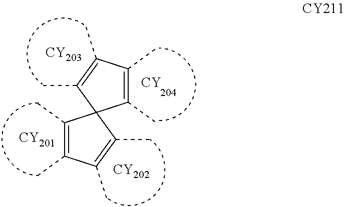

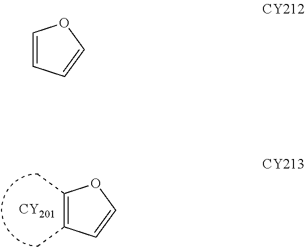

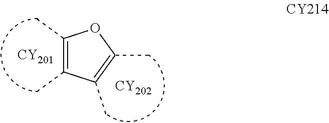

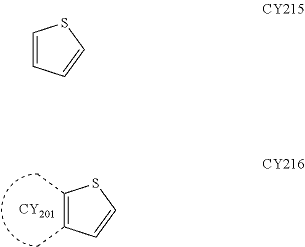

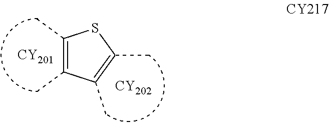

In Formulas CY201 to CY217, R_{10b} and R_{10c} may each independently be the same as described in connection with R₁₀ₐ in the specification, rings CY201 to CY204 may each independently be a C₃-C₂₀ carbocyclic group or a C₁-C₂₀ heterocyclic group, and at least one hydrogen in Formulas CY201 to CY217 may be unsubstituted or substituted with R₁₀ₐ as described herein.

According to an embodiment, in Formulas CY201 to CY217, rings CY201 to CY₂₀₄ may each independently be a benzene group, a naphthalene group, a phenanthrene group, or an anthracene group.

According to another embodiment, the compound represented by Formula 201 and the compound represented by Formula 202 may each independently include at least one of groups represented by Formulas CY201 to CY203.

According to another embodiment, the compound represented by Formula 201 may include at least one of groups represented by Formulas CY201 to CY203 and at least one of groups represented by Formulas CY204 to CY217.

According to another embodiment, in Formula 201, xa1 may be 1, R₂₀₁ may be a group represented by one of Formulas CY201 to CY203, xa2 may be 0, and R₂₀₂ may be a group represented by one of Formulas CY204 to CY207.

According to another embodiment, the compound represented by Formula 201 and the compound represented by Formula 202 may each not include groups represented by Formulas CY201 to CY203.

According to another embodiment, the compound represented by Formula 201 and the compound represented by Formula 202 may each not include groups represented by Formulas CY201 to CY203 and may each independently include at least one of groups represented by Formulas CY204 to CY217.

In an embodiment, the compound represented by Formula 201 and the compound represented by Formula 202 may each not include groups represented by Formulas CY201 to CY217.

In embodiments, the hole transport region may include one of Compounds HT1 to HT46, m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl)triphenylamine (TCTA), a polyaniline/dodecylbenzenesulfonic acid (Pani/DBSA), PEDOT/PSS, a polyaniline/camphor sulfonic acid (Pani/OSA), polyaniline/poly(4-styrenesulfonate) (PANI/PSS), or any combination thereof.

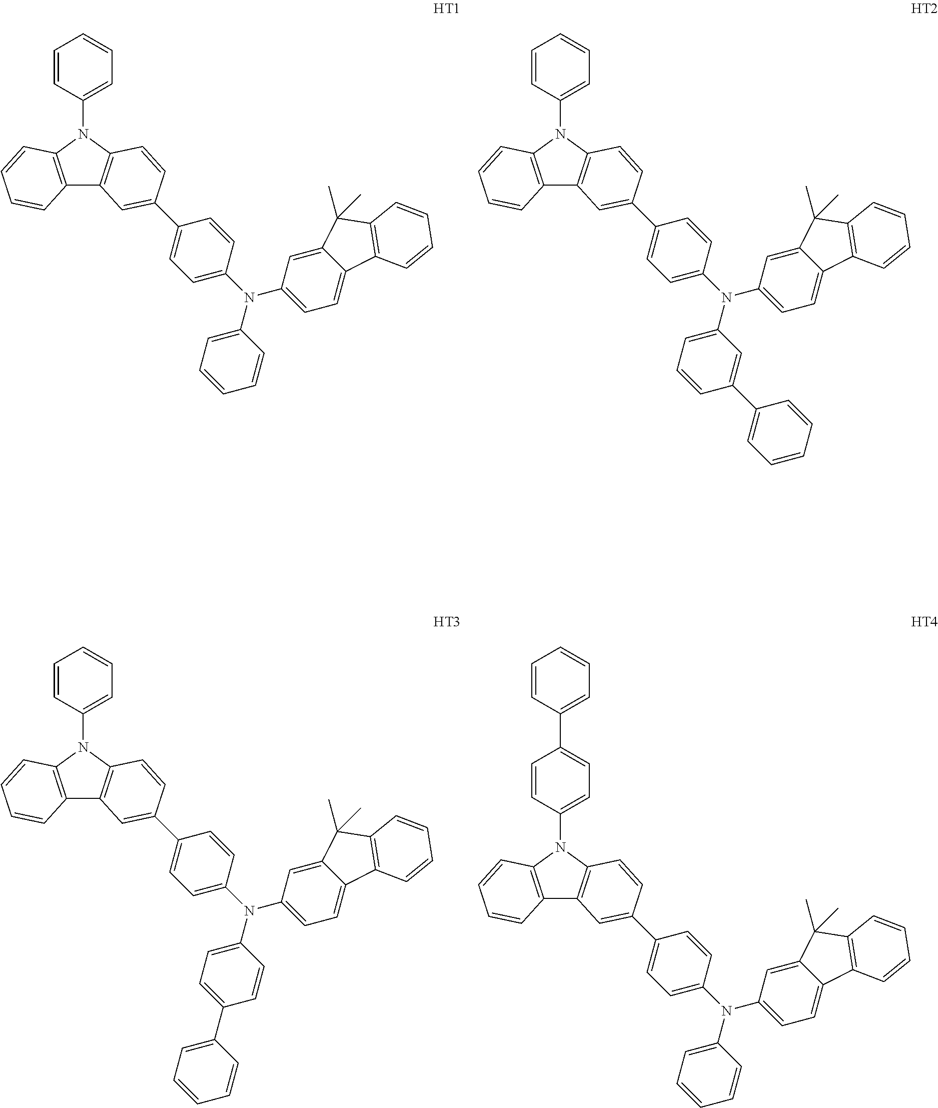 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

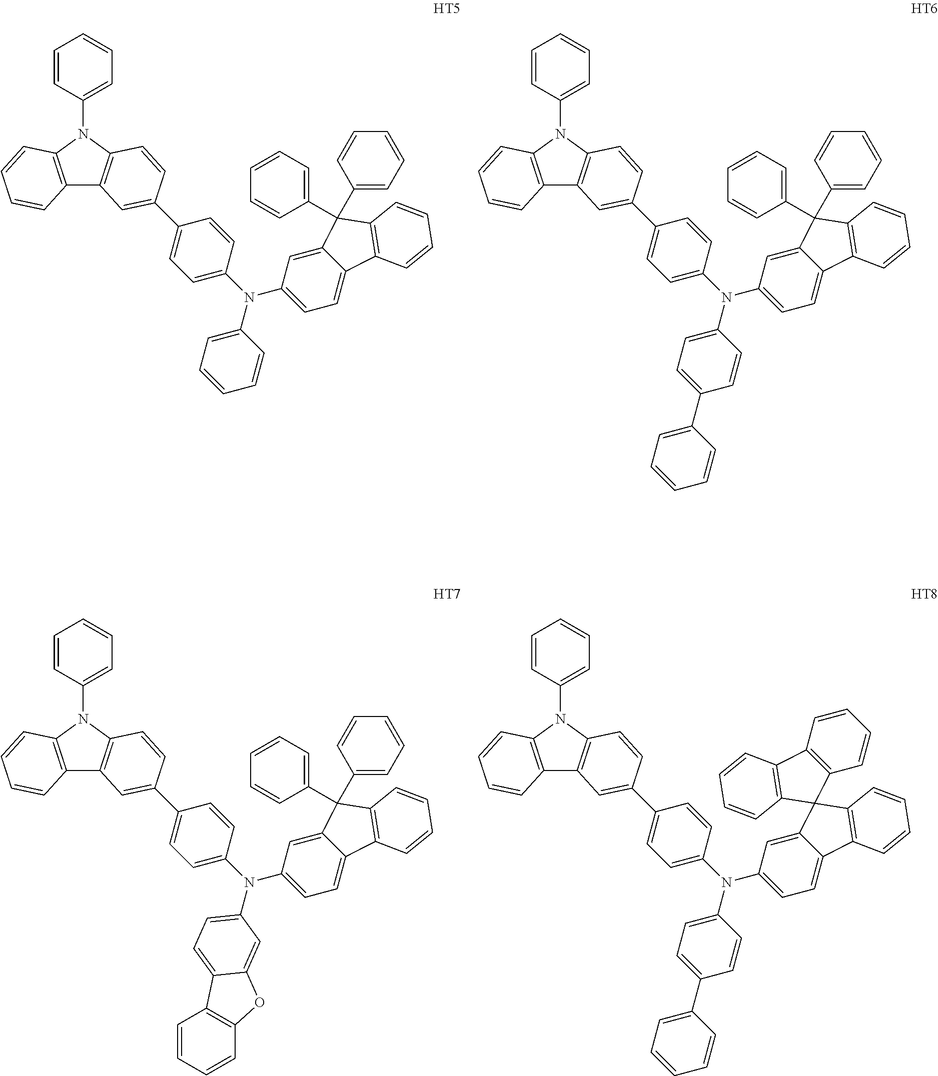 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

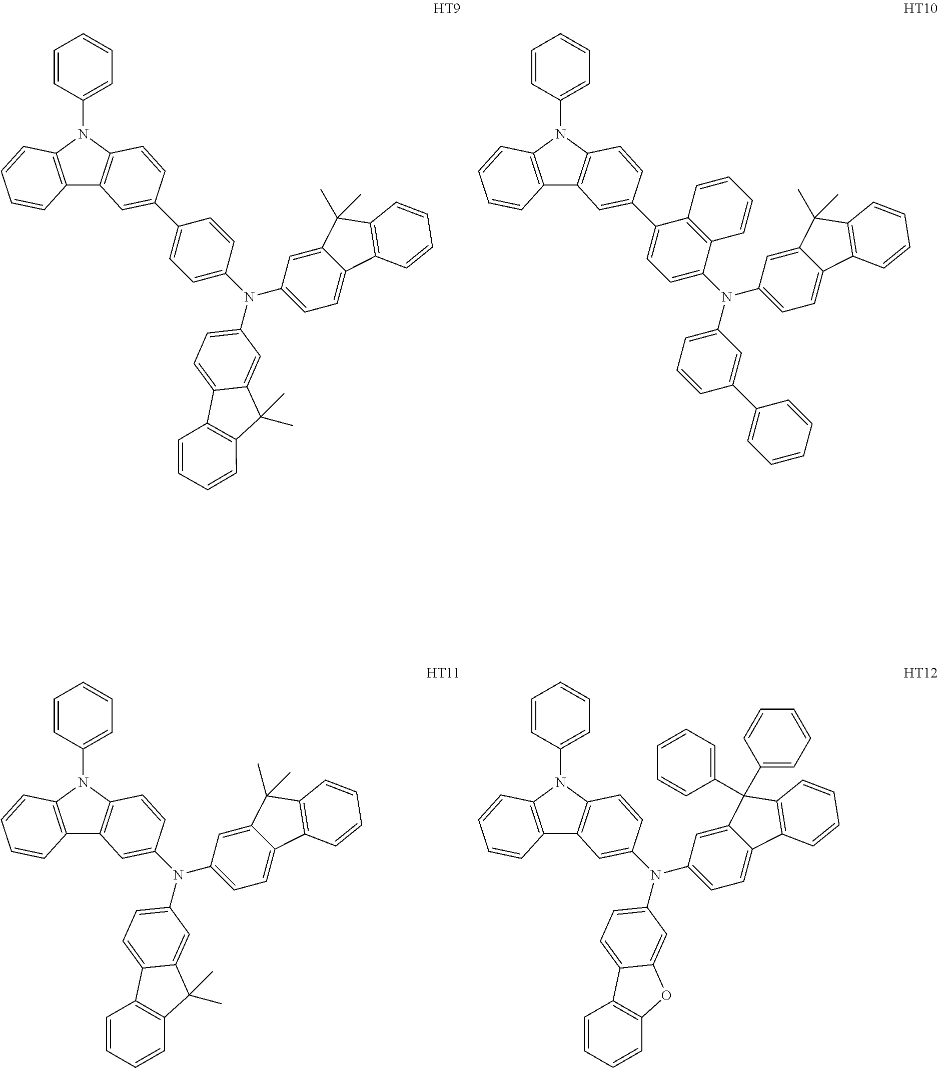 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

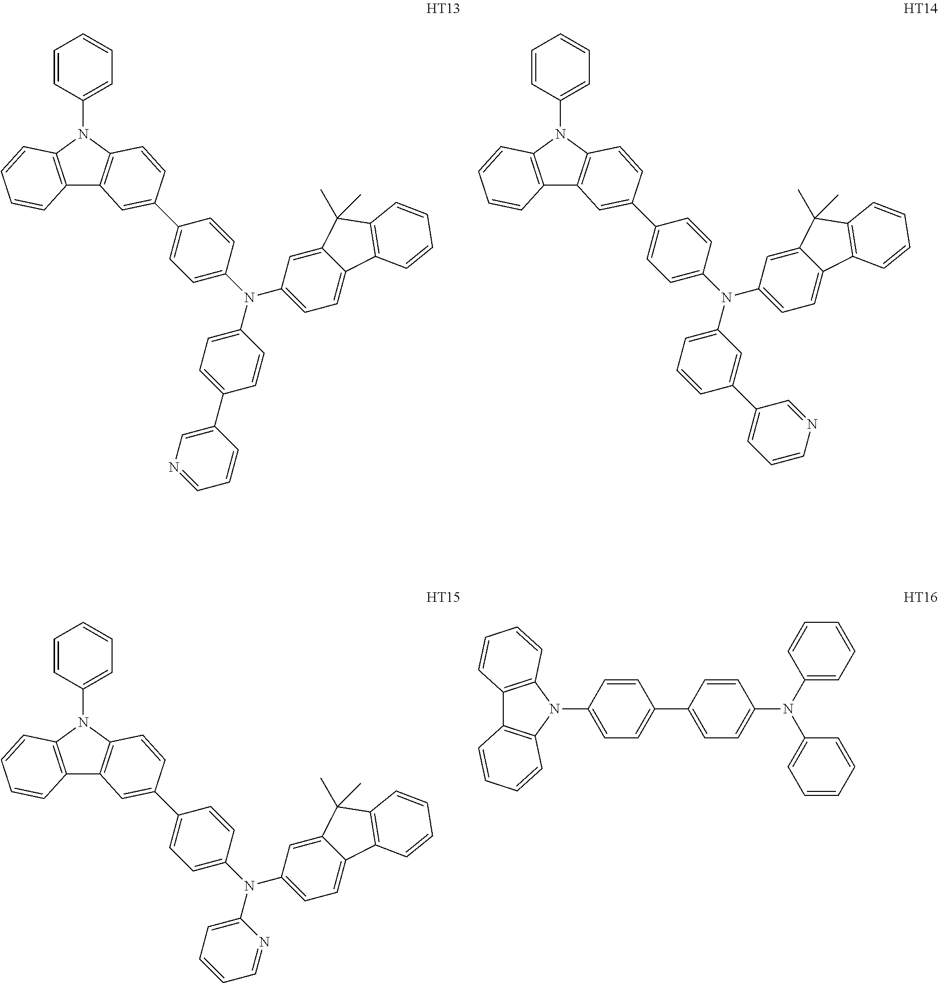 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

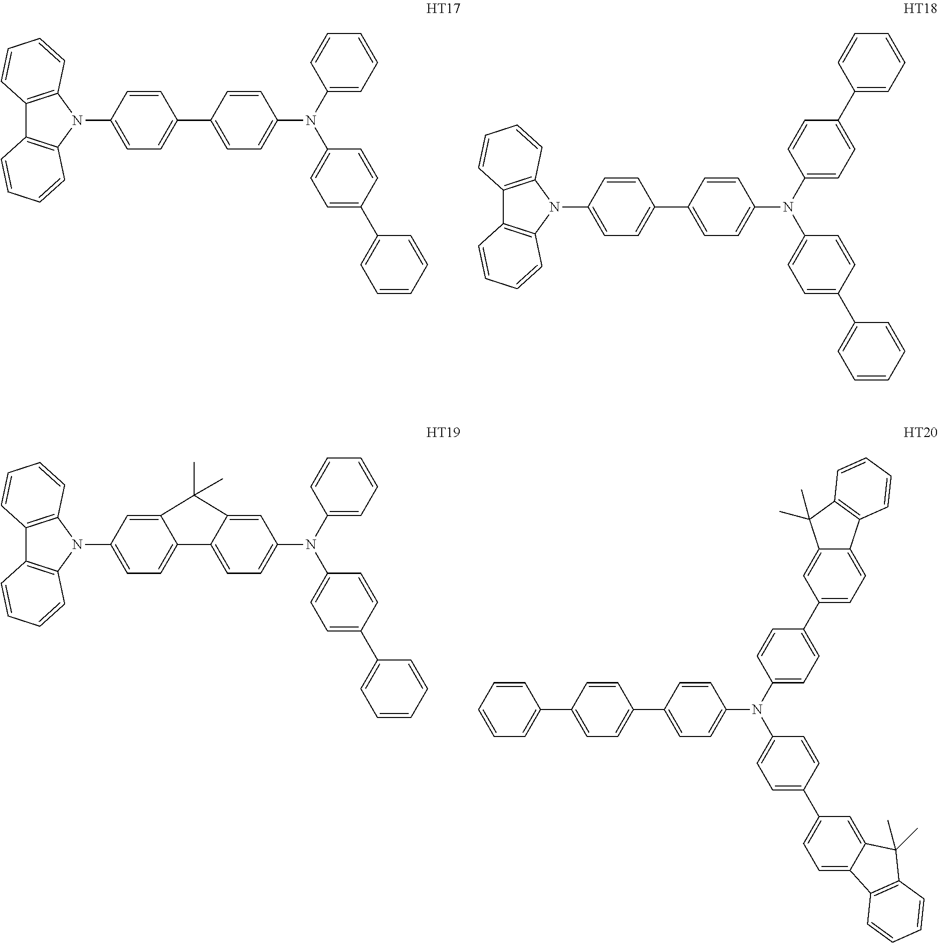 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

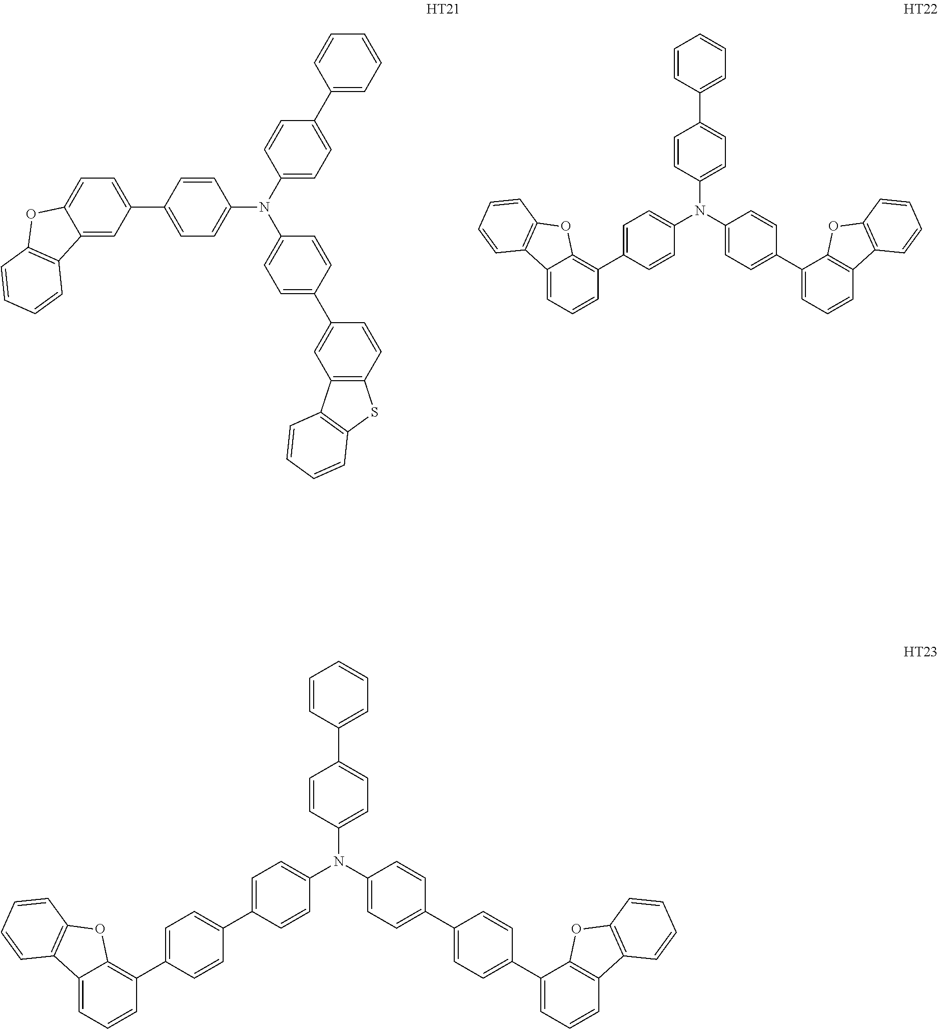 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

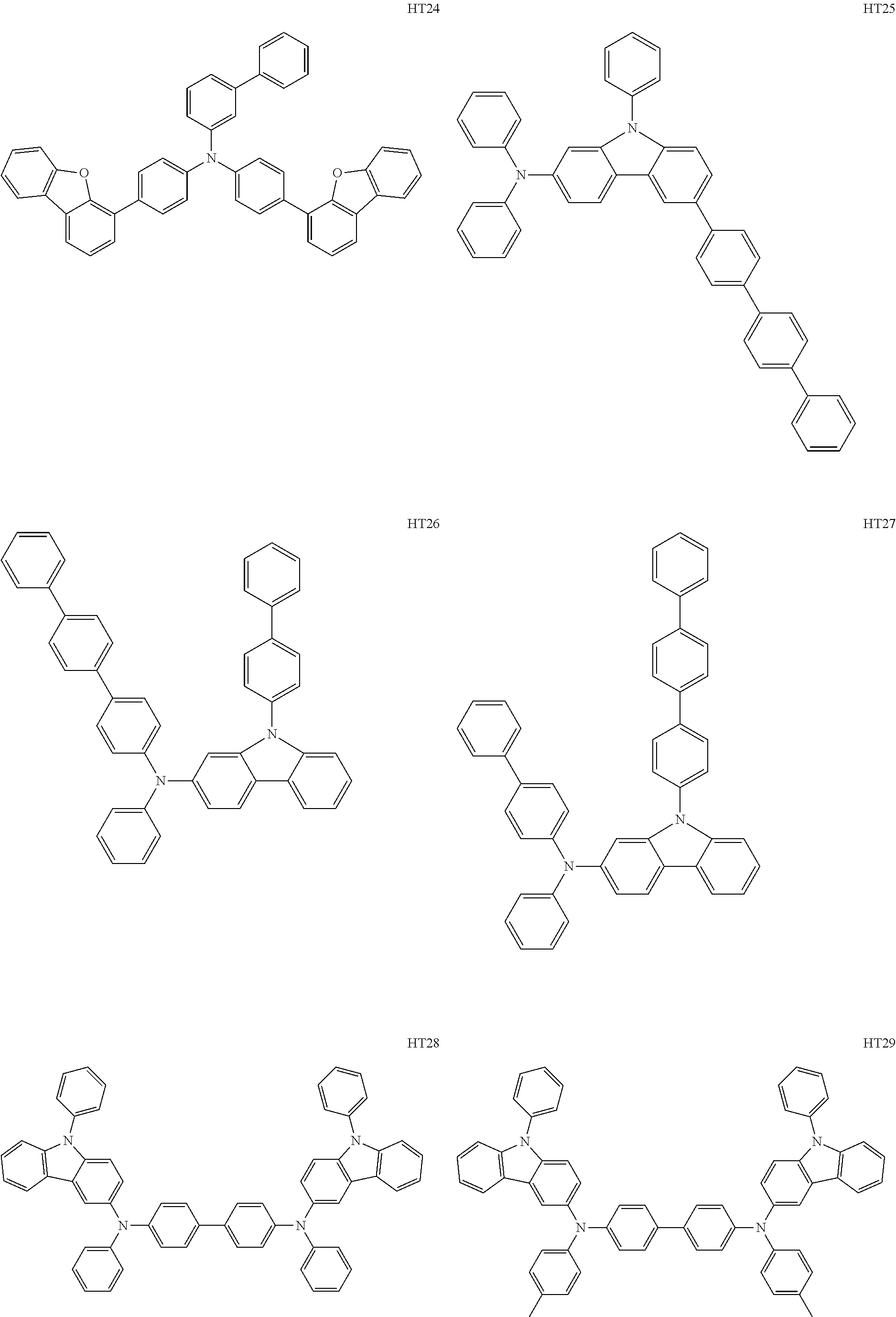

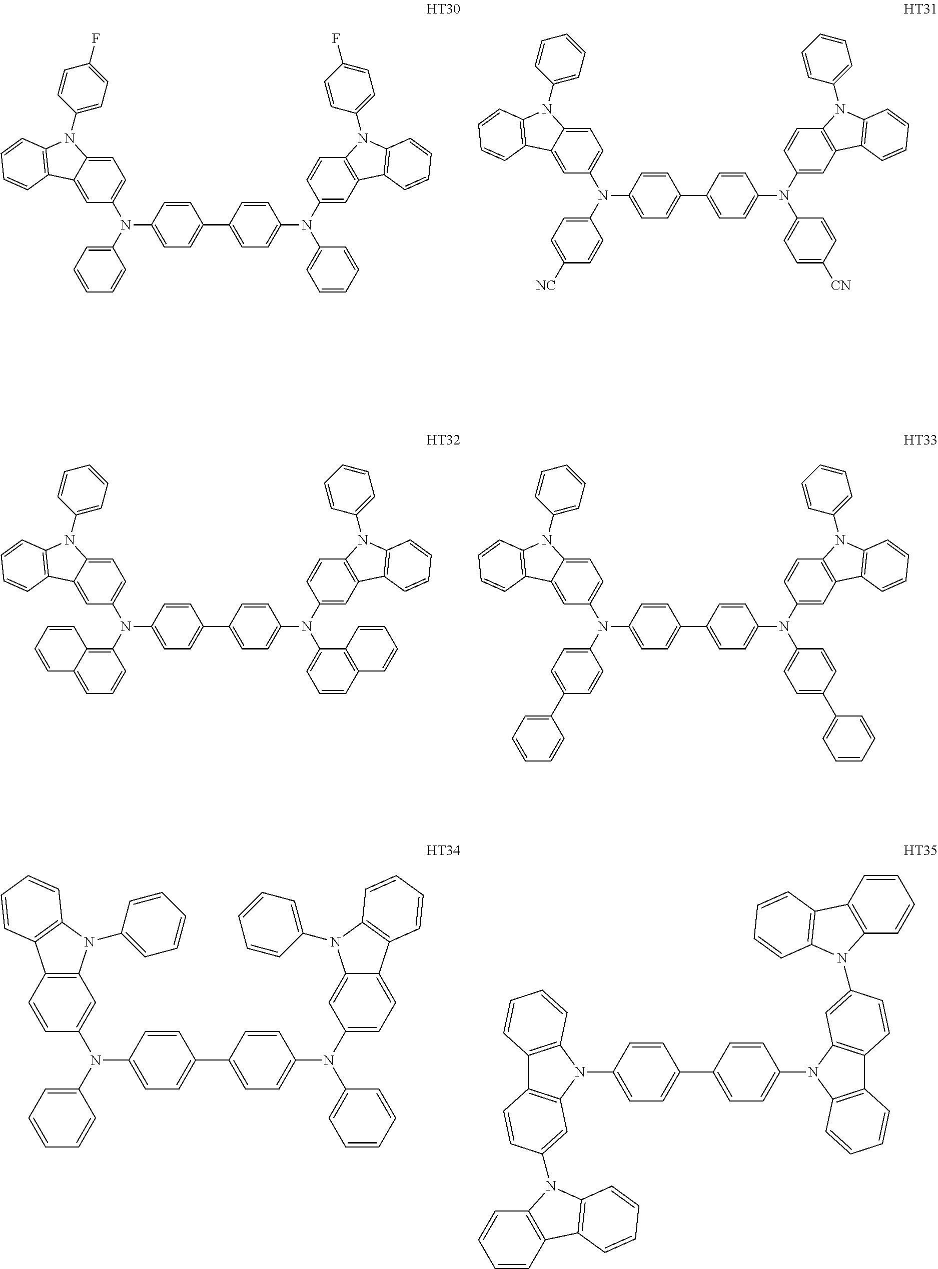

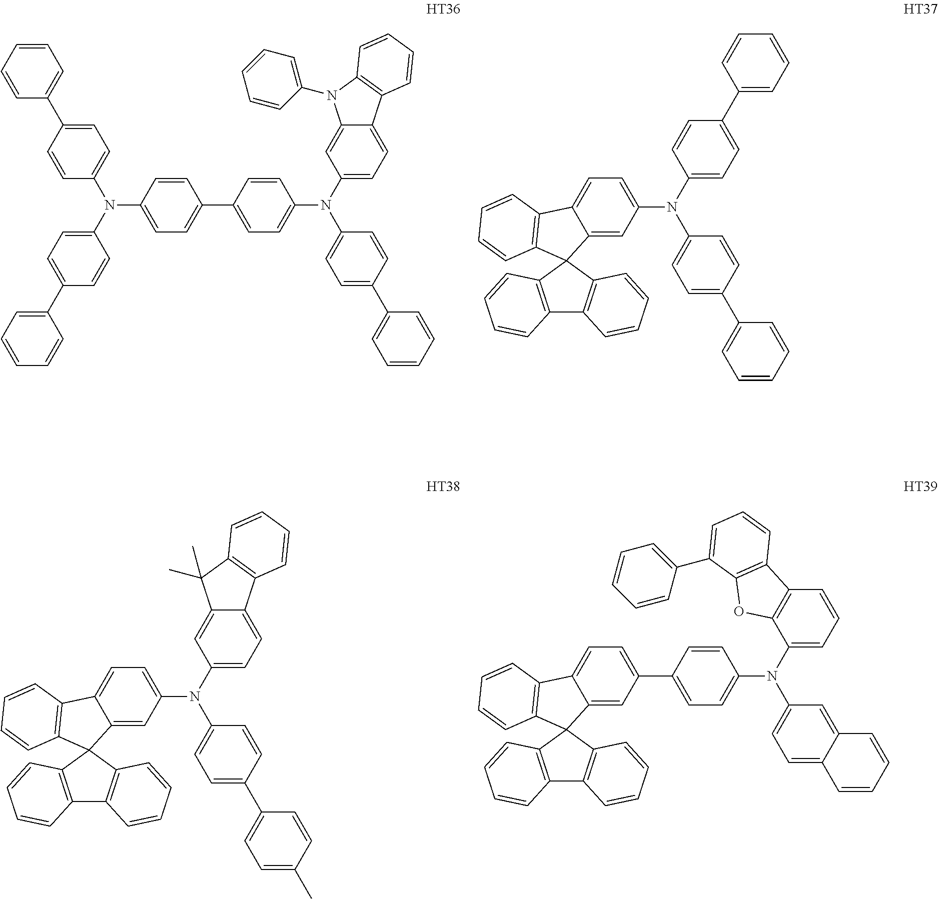 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

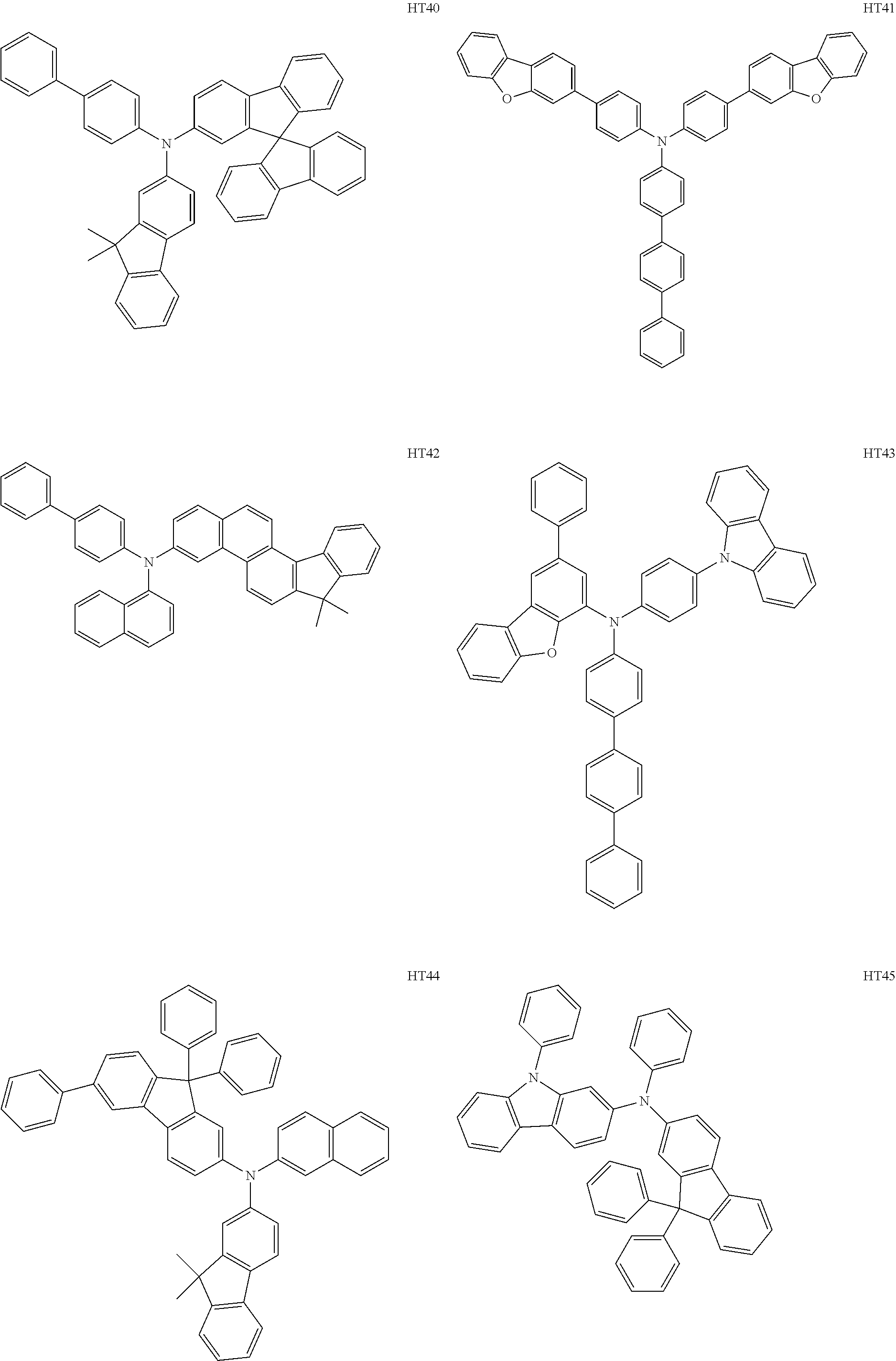

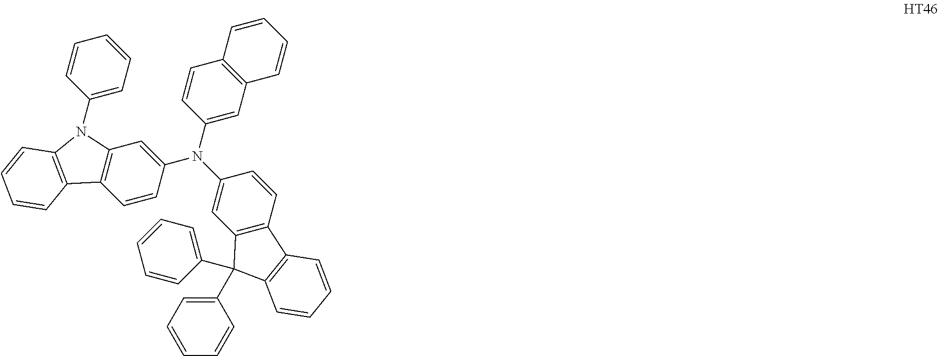 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

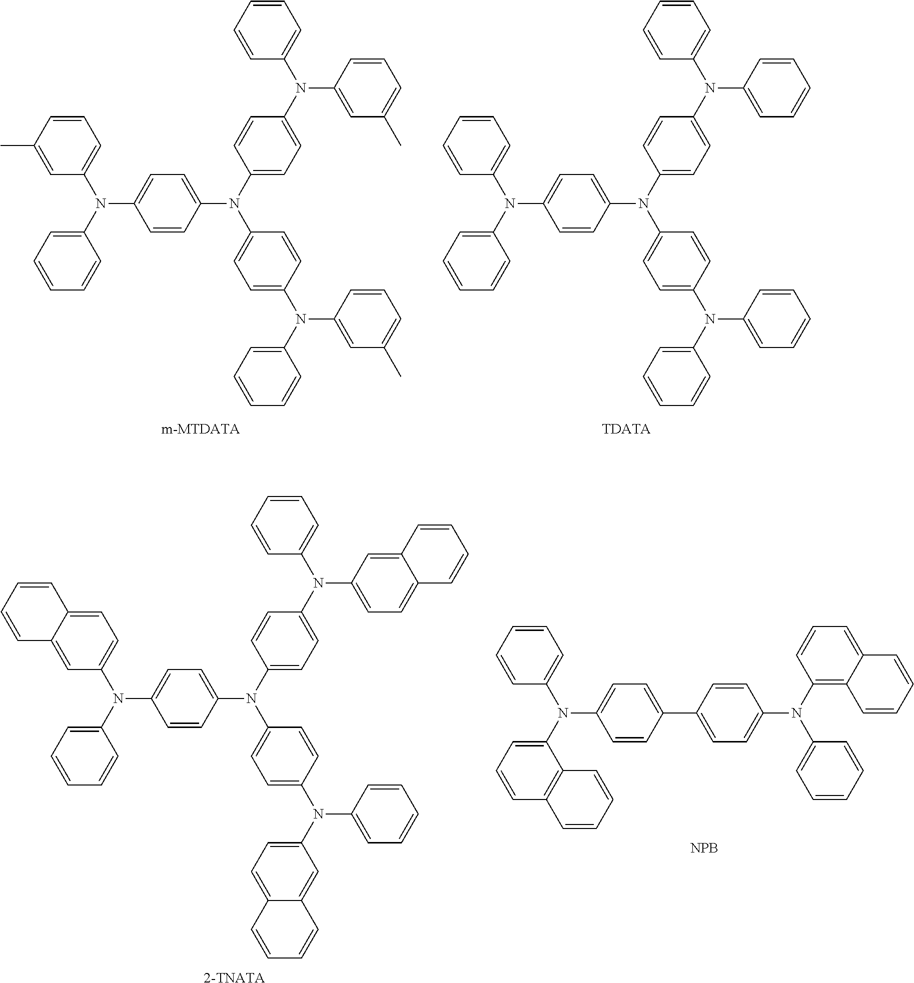

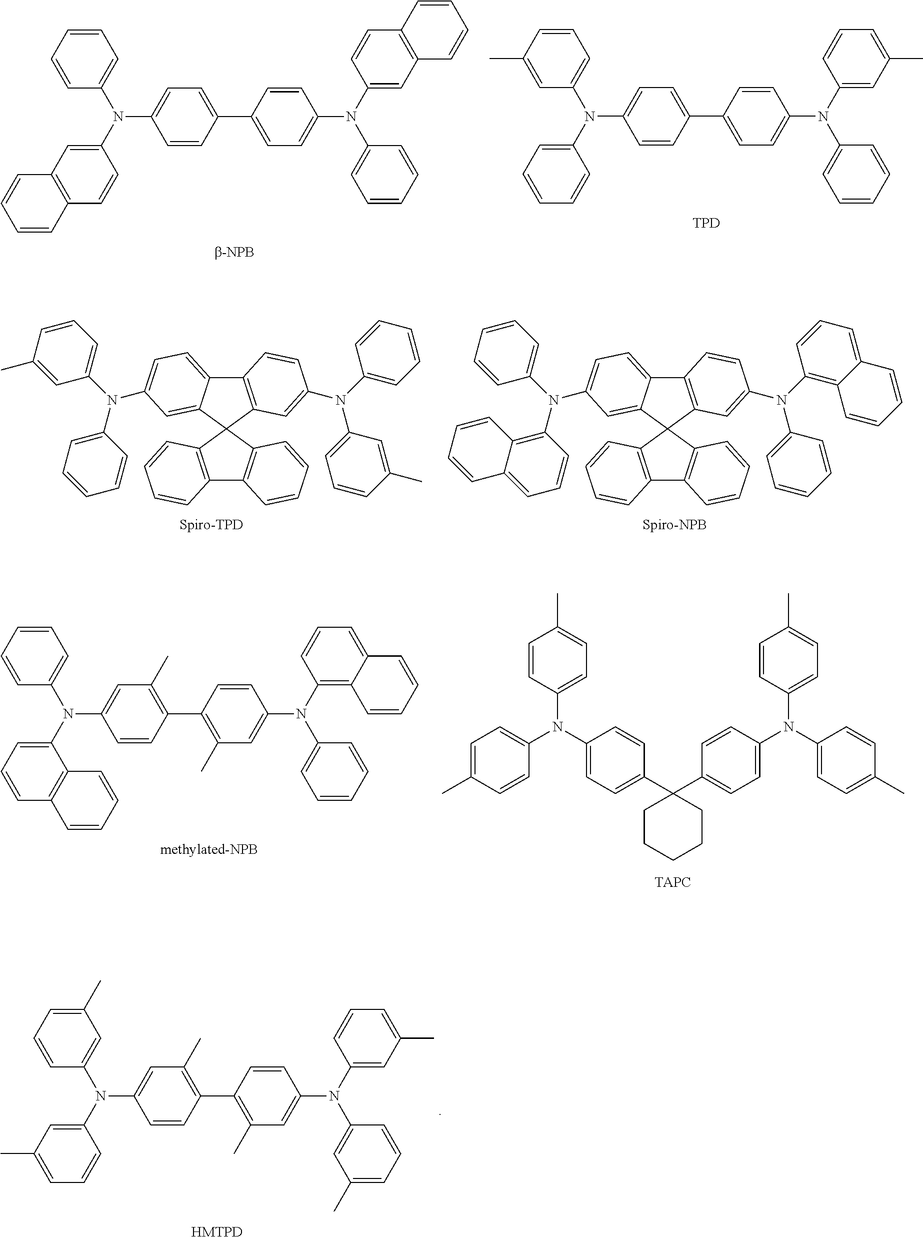

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer satisfy the ranges described above, satisfactory hole transport characteristics may be obtained without a substantial increase in driving voltage.

The emission auxiliary layer may be a layer that increases light emission efficiency by compensating for an optical resonance distance according to a wavelength of light emitted from the emission layer, and the electron blocking layer may be a layer that prevents electrons from leaking from the emission layer to the hole transport region. A material that may be included in the hole transport region described above may be included in the emission auxiliary layer and the electron blocking layer.

### [P-Dopant]

In addition to the materials described above, the hole transport region may further include a charge-generating material to improve conductivity. The charge-generating material may be uniformly or non-uniformly dispersed in the hole transport region (for example, in the form of a single layer consisting of a charge-generating material).

The charge-generating material may be, for example, a p-dopant.

In an embodiment, a lowest unoccupied molecular orbital (LUMO) energy level of the p-dopant may be less than or equal to about −3.5 eV.

According to an embodiment, the p-dopant may include a quinone derivative, a cyano group-containing compound, a compound containing element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like.

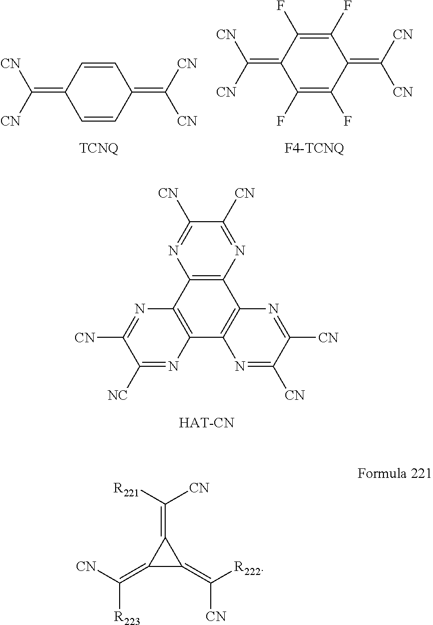

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may independently be: a cyano group; —F; —Cl; —Br; —I; a C₁-C₂₀ alkyl group substituted with a cyano group, —F, —Cl, —Br, —I, or any combination thereof; or a C₃-C₆₀ carbocyclic group or a C₁-C₆₀ heterocyclic group substituted with any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (for example, lithium (Li), sodium (Na), potassium (K), rubidium (Rb), or cesium (Cs)); an alkali earth metal (for example, beryllium (Be), magnesium (Mg), calcium (Ca), strontium (Sr), and barium (Ba)); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), and gold (Au)); a post-transition metal (for example, zinc (Zn), indium (In), and tin (Sn)); a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and ruthenium (Lu)); and the like.

Examples of a metalloid may include silicon (Si), antimony (Sb), tellurium (Te), and the like.

Examples of a non-metal may include oxygen (O), a halogen (for example, F, Cl, Br, or I), and the like.

Examples of a compound including element EL1 and element EL2 may include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), a metal telluride, or any combination thereof.

Examples of a metal oxide may include a tungsten oxide (for example, WO, W₂O₃, WO₂, WO₃, or W₂O₅), a vanadium oxide (for example, VO, V₂O₃, VO₂, or V₂O₅), a molybdenum oxide (MoO, Mo₂O₃, MoO₂, MoO₃, Mo₂O₅, or the like), a rhenium oxide (for example, ReO₃), and the like.

Examples of a metal halide may include an alkali metal halide, an alkali earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, Rbl, CsI, and the like.

Examples of an alkali earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, Bel₂, Mg₁₂, Cal₂, Srl₂, Bal₂, and the like.

Examples of a transition metal halide may include a titanium halide (for example, TiF₄, TiCl₄, TiBr₄, or Til₄), a zirconium halide (for example, ZrF₄, ZrC₁₄, ZrBr₄, or Zr₁₄), a hafnium halide (for example, HfF₄, HfC₁₄, HfBr₄, or Hfl₄), a vanadium halide (for example, VF₃, VCl₃, VBr₃, or VI₃), a niobium halide (for example, NbF₃, NbCl₃, NbBr₃, or Nbl₃), a tantalum halide (for example, TaF₃, TaCl₃, TaBr₃, or Talk), a chromium halide (for example, CrF₃, Cr₀₃, CrBr₃, or CrI₃), a molybdenum halide (for example, MoF₃, MoCl₃, MoBr₃, or MoI₃), a tungsten halide (for example, WF₃, WCl₃, WBr₃, or WI₃), a manganese halide (for example, MnF₂, MnCl₂, MnBr₂, or MnI₂), a technetium halide (for example, TcF₂, TcCl₂, TcBr₂, or TcI₂), a rhenium halide (for example, ReF₂, ReCl₂, ReBr₂, or ReI₂), an iron halide (for example, FeF₂, FeCl₂, FeBr₂, or FeI₂), a ruthenium halide (for example, RuF₂, RuCl₂, RuBr₂, or RuI₂), an osmium halide (for example, OsF₂, OsCl₂, OsBr₂, or OsI₂), a cobalt halide (for example, CoF₂, COCl₂, CoBr₂, or CoI₂), a rhodium halide (for example, RhF₂, RhCl₂, RhBr₂, or RhI₂), an iridium halide (for example, IrF₂, IrCl₂, IrBr₂, or IrI₂), a nickel halide (for example, NiF₂, NiCl₂, NiBr₂, or NiI₂), a palladium halide (for example, PdF₂, PdCl₂, PdBr₂, or PdI₂), a platinum halide (for example, PtF₂, PtCl₂, PtBr₂, or PtI₂), a copper halide (for example, CuF, CuCl, CuBr, or CuI), a silver halide (for example, AgF, AgCl, AgBr, or AgI), a gold halide (for example, AuF, AuCl, AuBr, or Aul), and the like.

Examples of a post-transition metal halide may include a zinc halide (for example, ZnF₂, ZnCl₂, ZnBr₂, or ZnI₂), an indium halide (for example, Inks), a tin halide (for example, SnI₂), and the like.

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of a metalloid halide may include an antimony halide (for example, SbCl₅), and the like.

Examples of a metal telluride may include an alkali metal telluride (for example, Li₂Te, Na₂Te, K₂Te, Rb₂Te, or Cs₂Te), an alkali earth metal telluride (for example, BeTe, MgTe, CaTe, SrTe, or BaTe), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, or Au₂Te), a post-transition metal telluride (for example, ZnTe), a lanthanide metal telluride (for example, LaTe, CeTe, PrTe, NdTe, PmTe, EuTe, GdTe, TbTe, DyTe, HoTe, ErTe, TmTe, YbTe, or LuTe), and the like.

### [Emission Layer in Interlayer 130]

The emission layer may include the quantum dot as described herein.

In addition to the quantum dot described herein, the emission layer may further include a dispersion medium in which the quantum dot is dispersed in a naturally coordinated form. The dispersion medium may include an organic solvent, a polymer resin, or any combination thereof. Any transparent medium may be used as the dispersion medium as long as the transparent medium does not affect the optical performance of the quantum dot, is not deteriorated by light, and does not absorb light. For example, the organic solvent may include toluene, chloroform, ethanol, octane, or any combination thereof, and the polymer resin may include an epoxy resin, a silicone resin, a polystyrene resin, an acrylate resin, or any combination thereof.

The emission layer may be formed by applying an emission layer-forming composition that includes quantum dots onto a hole transport region and volatilizing at least a portion of a solvent included in the emission layer-forming composition.

In an embodiment, water, hexane, chloroform, toluene, octane, or the like may be used as the solvent.

The emission layer-forming composition may be applied by using spin coating, casting, micro-gravure coating, gravure coating, bar coating, roll coating, wire bar coating, dip coating, spray coating, screen printing, flexographic printing, offset printing, inkjet printing, or the like.

When the light-emitting device 300 is a full-color light-emitting device, the emission layer may include emission layers that emit light having different colors for each subpixel.

In an embodiment, the emission layer may be patterned into a first color emission layer, a second color emission layer, and a third color emission layer for each subpixel. In an embodiment, at least one emission layer of the above-described emission layers may include the quantum dots as described herein. For example, the first color emission layer may be a quantum dot emission layer including quantum dots, and the second color emission layer and the third color emission layer may each be an organic emission layer including an organic compound. In an embodiment, first to third colors may be different colors, and light having the first to third colors may have different maximum emission wavelengths. The first to third colors may be combined with each other to become a white color.

In another embodiment, the emission layer may further include a fourth color emission layer. Various modifications are possible in which at least one emission layer among the first to fourth color emission layers is a quantum dot emission layer including quantum dots, and the remaining emission layers thereof are each an organic emission layer including an organic compound. In an embodiment, first to fourth colors may be different colors, and light having the first to fourth colors may have different maximum emission wavelengths. The first to fourth colors may be combined with each other to become a white color.

In an embodiment, the light-emitting device 300 may have a structure in which two or more emission layers emitting light having the same or different colors are stacked to contact each other or to be spaced apart from each other. Various modifications are possible in which at least one emission layer among the two or more emission layers is a quantum dot emission layer including quantum dots, and the remaining emission layers thereof are organic emission layers including an organic compound. For example, the light-emitting device 300 may include a first color emission layer and a second color emission layer, wherein first color and second color may be the same color or different colors. For example, both the first color and the second color may be a green color or a blue color.

In addition to the quantum dot, the emission layer may further include at least one of an organic compound and a semiconductor compound.

For example, the organic compound may include a host and a dopant. The host and the dopant may include a host and a dopant of the related art that is used in organic light-emitting devices.

For example, the semiconductor compound may be an organic and/or inorganic perovskite.

### [Electron Transport Region of Interlayer 130]

The electron transport region may have a structure consisting of a single material, a structure consisting of a layer including different materials, or a structure including multiple layers including different materials.

The electron transport region may include at least one of a buffer layer, a hole blocking layer, an electron control layer, an electron transport layer, and an electron injection layer, but embodiments are not limited thereto.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may bey stacked from an emission layer in its respective stated order, but embodiments are not limited thereto.

In an embodiment, the electron transport region may include a conductive metal oxide or an organic material. The conductive metal oxide may include, for example, ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-Doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg doped-BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

In an embodiment, the electron transport region may include a compound represented by Formula 601:

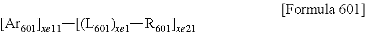

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁₁ in the specification,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group substituted or unsubstituted with at least one R₁₀ₐ.

In an embodiment, in Formula 601, when xe11 is 2 or more, two or more of Ar₆₀₁ may be linked to each other through a single bond.

In an embodiment, in Formula 601, Ar₆₀₁ may be an anthracene group unsubstituted or substituted with at least one R₁₀ₐ.

In an embodiment, the electron transport region may include a compound represented by Formula 601-1:

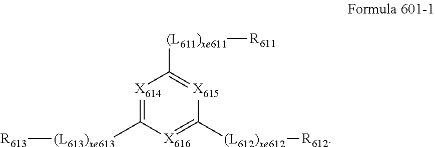

In Formula 601-1,
X₆₁₄ may be N or C (R₆₁₄), X₆₁₅ may be N or C (R₆₁₅), X₆₁₆ may be N or C (R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection withxel,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, in Formula 601 and Formula 601-1, xe1 and xe611 to xe613 may each independently be 0, 1, or 2.

In an embodiment, the electron transport region may include one of Compounds ET1 to ET45, BCP (2,9-dimethyl-4,7-diphenyl-1,10-phenanthroline), Bphen (4,7-diphenyl-1,10-phenanthroline), Alq3, BAlq, TAZ, NTAZ, or any combination thereof:

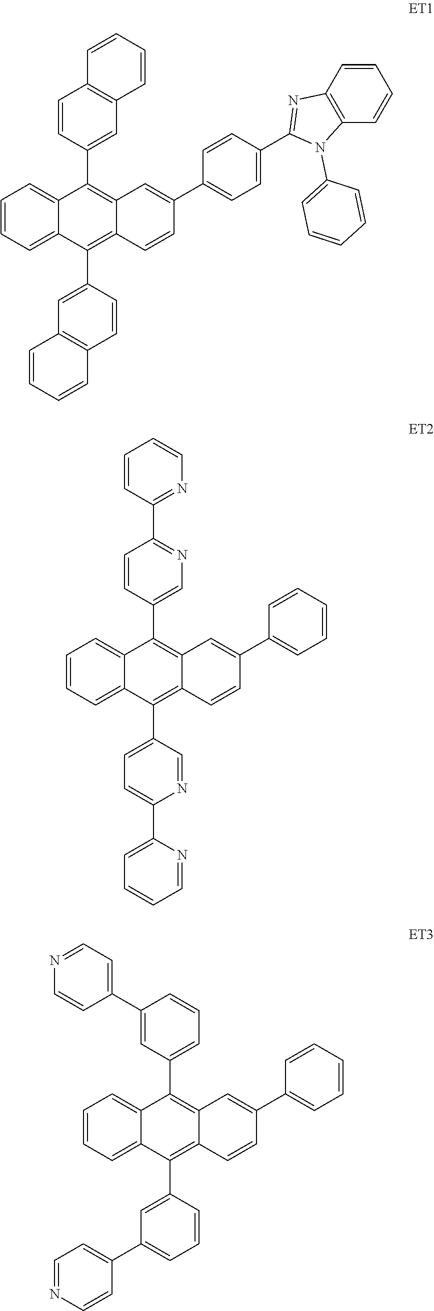 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

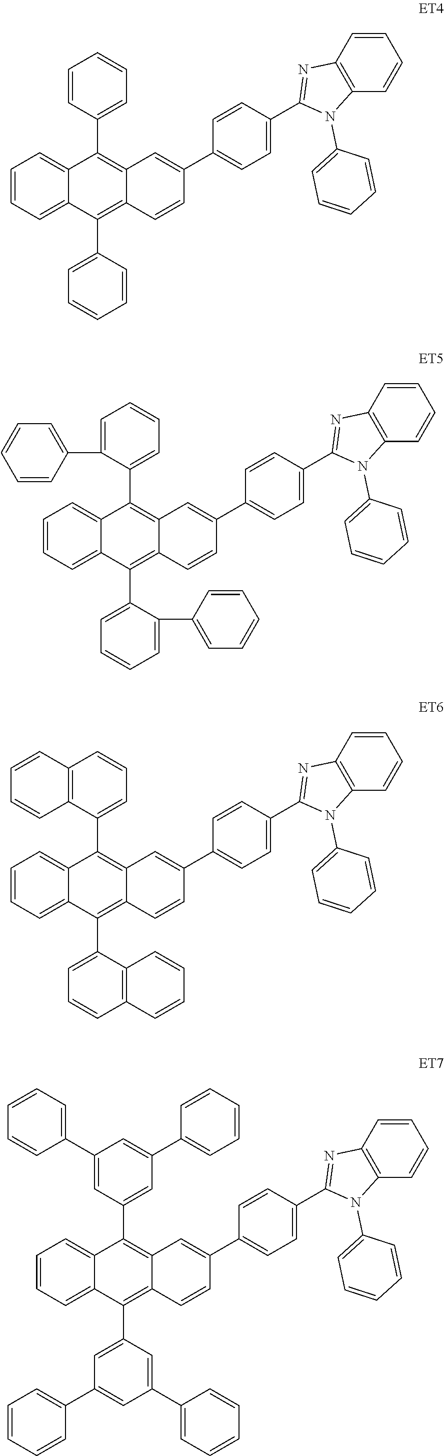 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

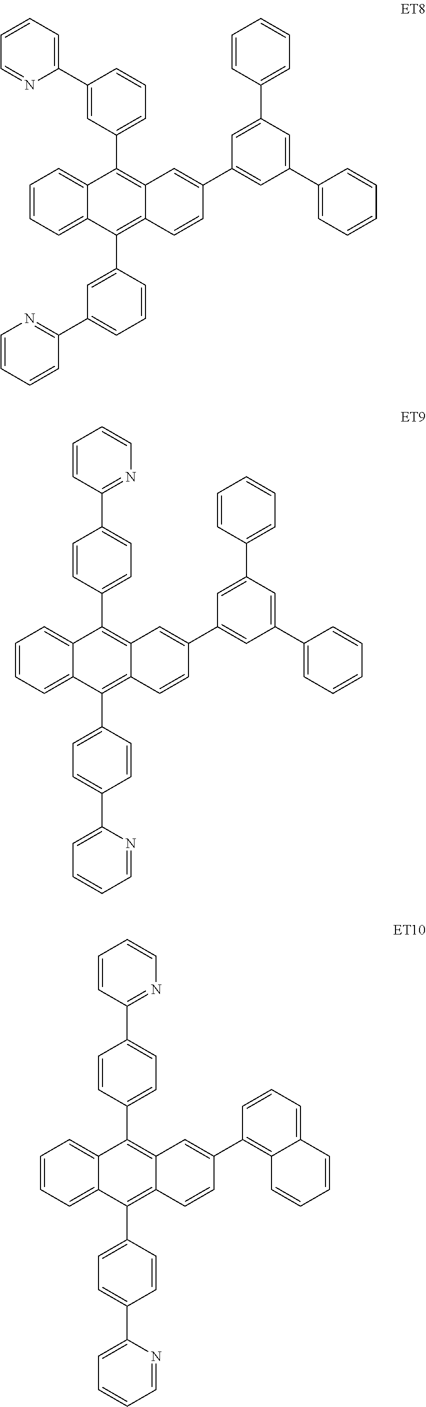 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

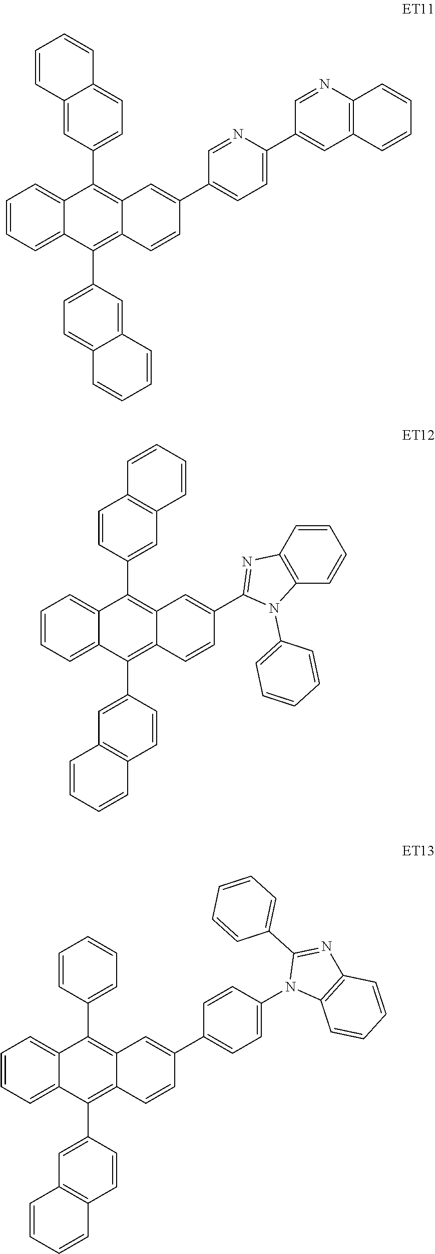 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

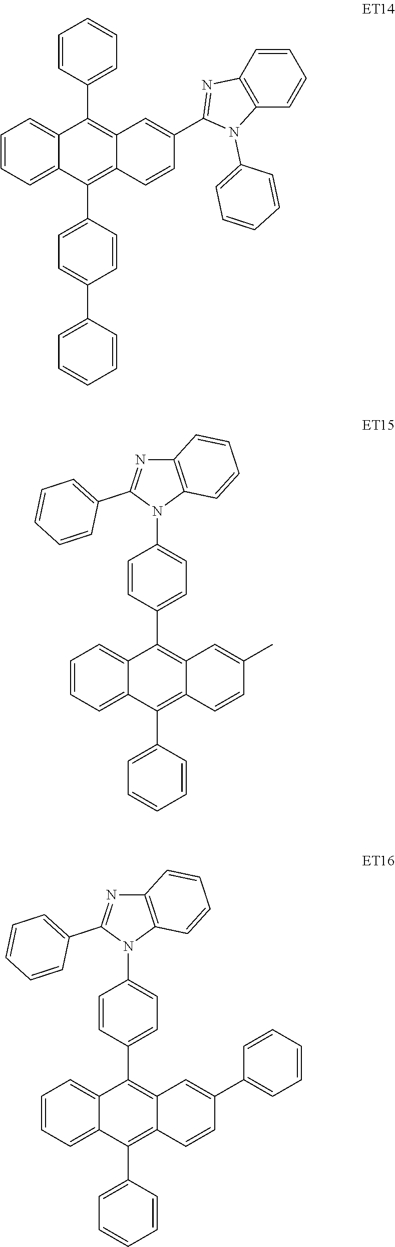 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

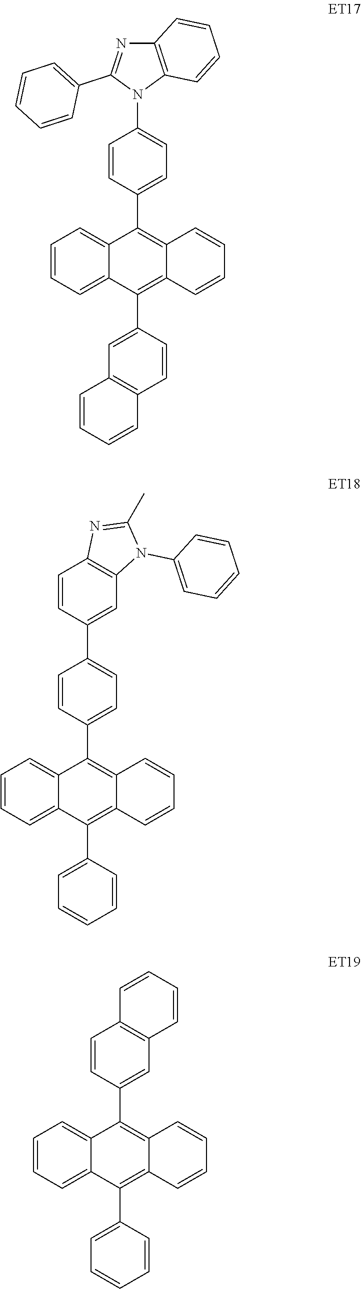

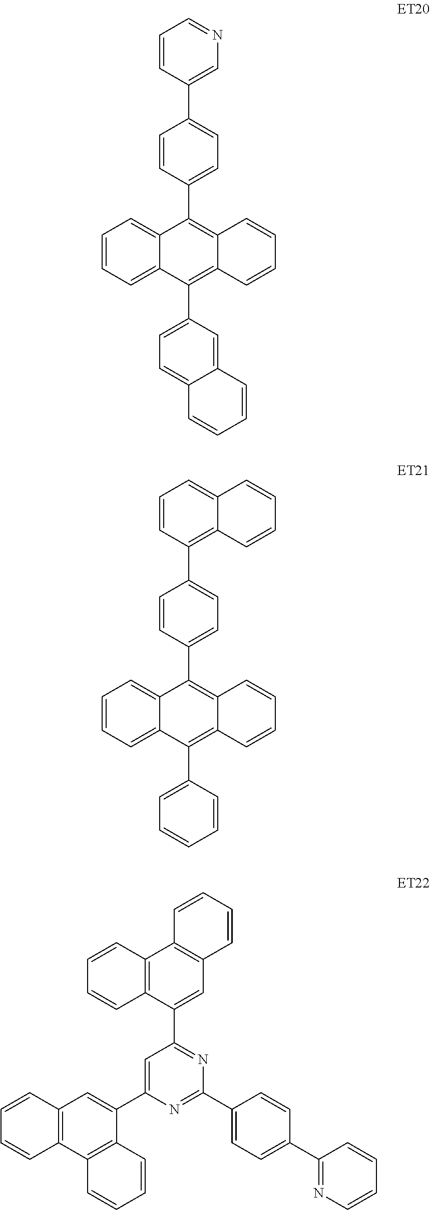

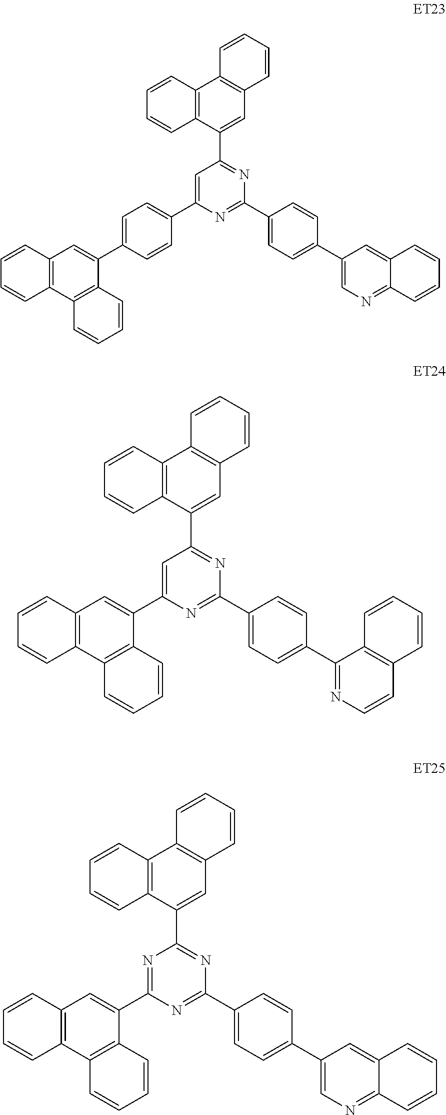 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

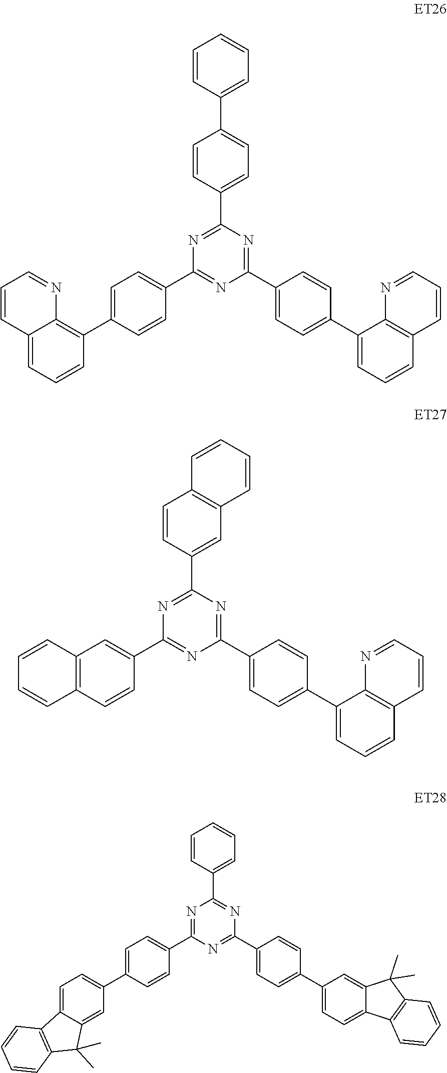 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

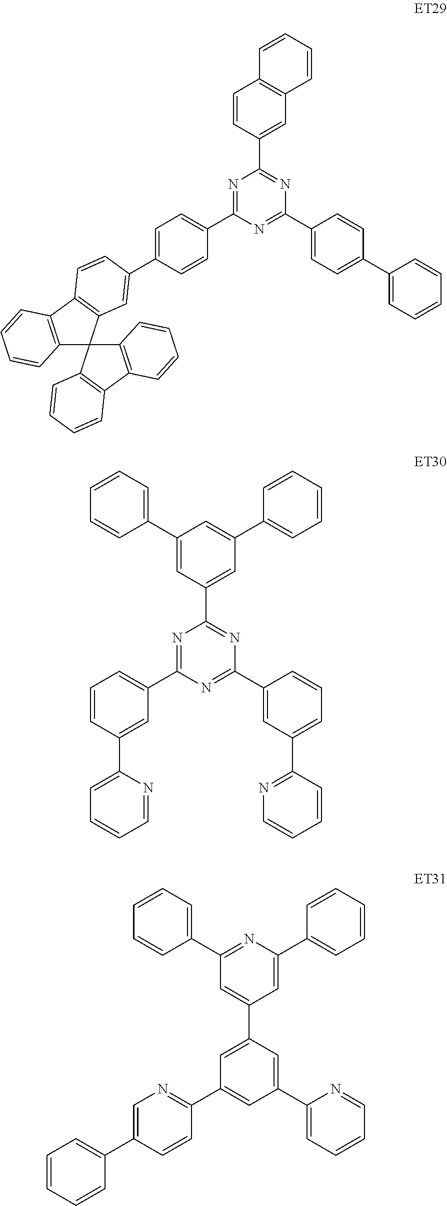 [SMILES: c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

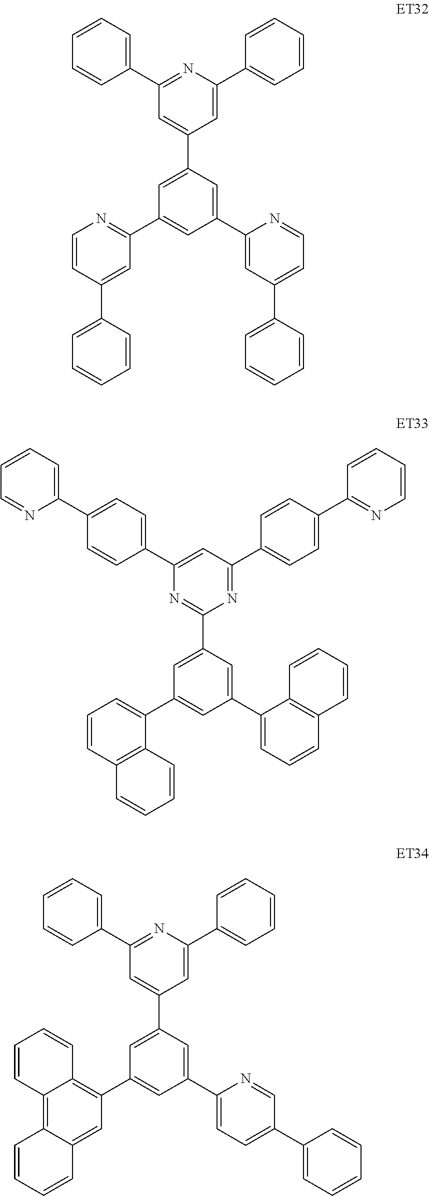 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

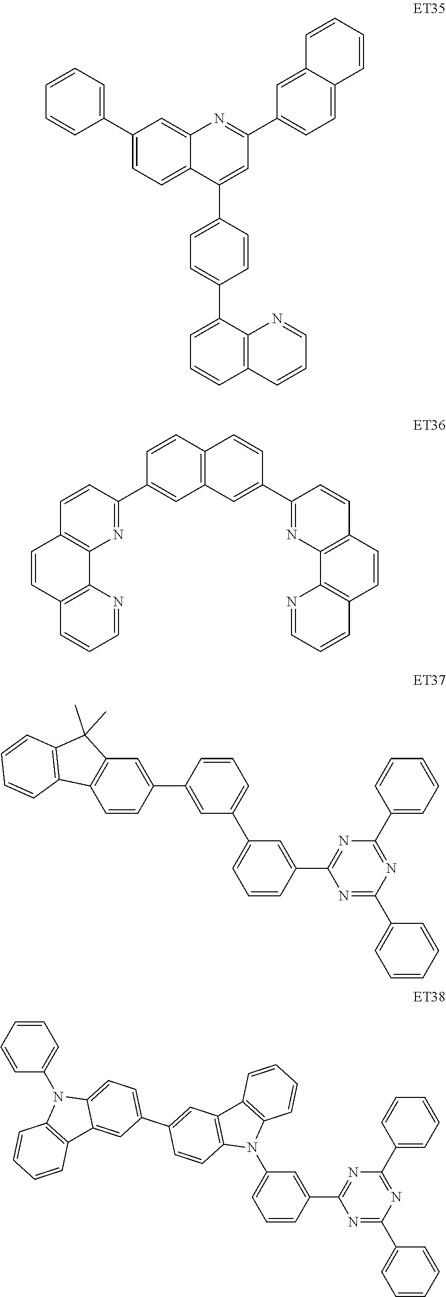 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

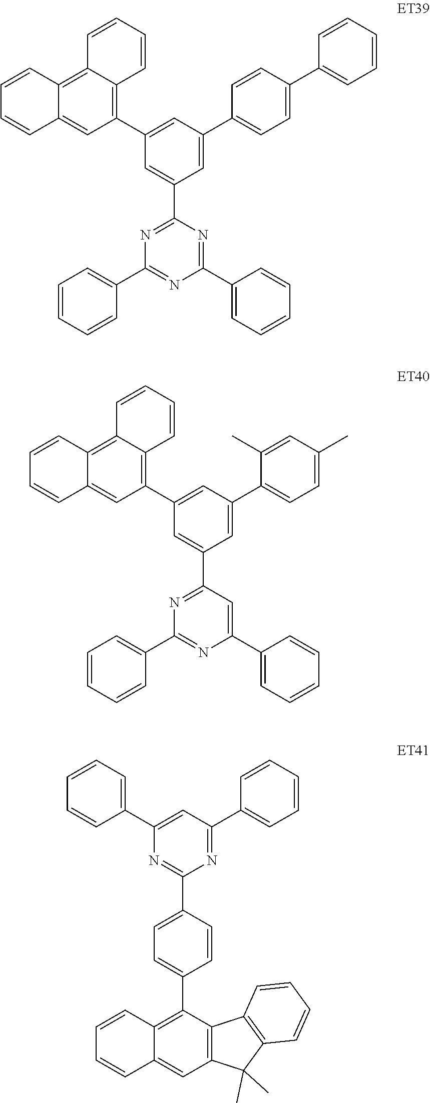 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

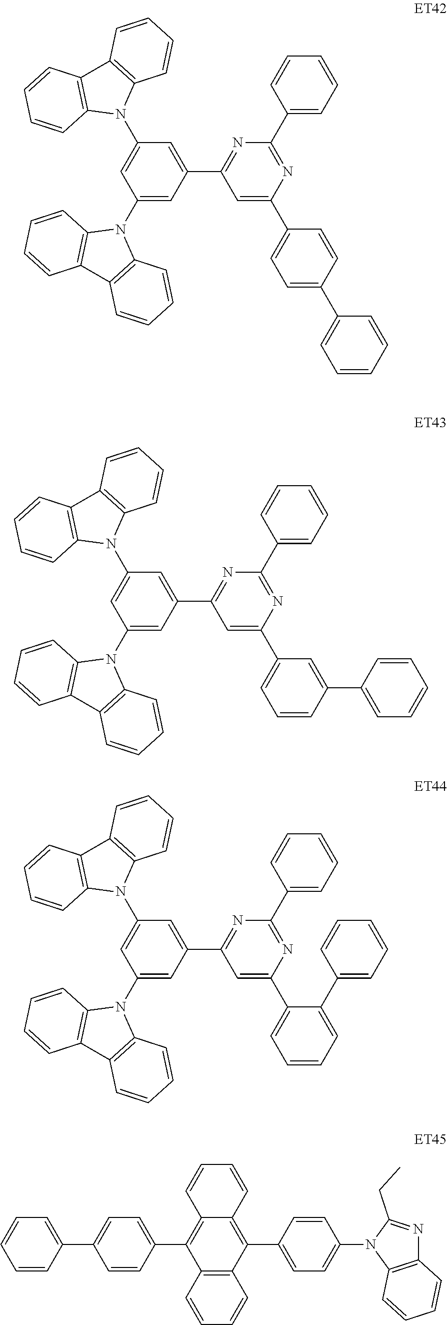

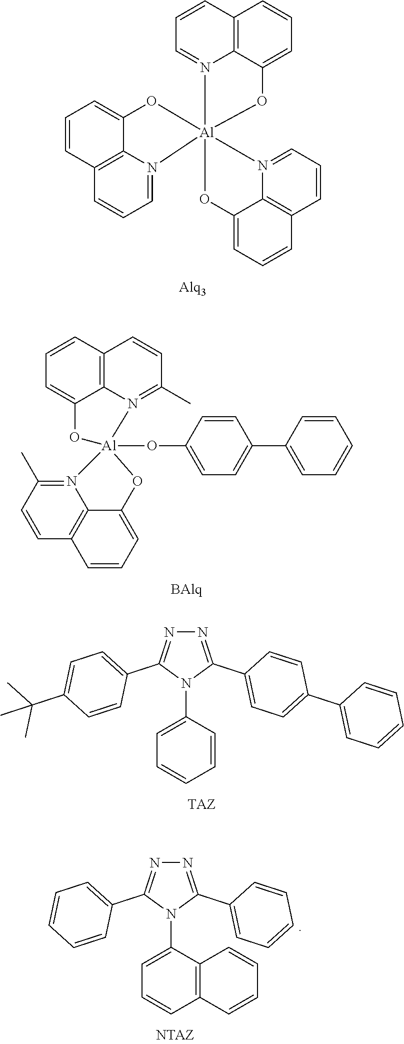

A thickness of the electron transport region may be in a range of about 100 Å to about 5,000 Å. For example, the thickness of the electron transport region may be in a range of about 160 Å to about 4,000 Å. When the electron transport region includes a buffer layer, a hole blocking layer, an electron control layer, an electron transport layer, or any combination thereof, a thickness of the buffer layer, the hole blocking layer, and the electron control layer may each independently be in a range of about 20 Å to about 1,000 Å, and a thickness of the electron transport layer may be in a range of about 100 Å to about 1,000 Å. For example, the thickness of the buffer layer, the hole blocking layer, and the electron control layer may each independently be in a range of about 30 Å to about 300 Å. For example, the thickness of the electron transport layer may be in a range of about 150 Å to about 500 Å. When the thicknesses of the buffer layer, the hole blocking layer, the electron control layer, the electron transport layer, and/or the electron transport region satisfy the ranges described above, satisfactory electron transport characteristics may be obtained without a substantial increase in driving voltage.

The electron transport region (for example, an electron transport layer in the electron transport region) may further include a metal-containing material in addition to the materials described above.

The metal-containing material may include an alkali metal complex, an alkali earth metal complex, or any combination thereof. A metal ion of the alkali metal complex may be a Li ion, a Na ion, a K ion, a Rb ion, or a Cs ion, and a metal ion of the alkali earth metal complex may be a Be ion, a Mg ion, a Ca ion, a Sr ion, or a Ba ion. A ligand coordinated with a metal ion of an alkali metal complex or with a metal ion of an alkali earth metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzoimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

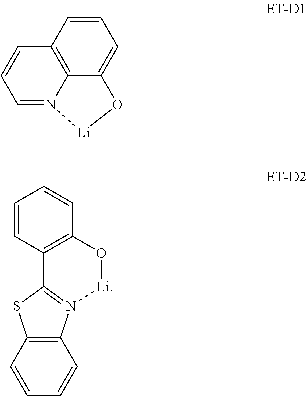

The electron transport region may include an electron injection layer that facilitates the injection of electrons from the second electrode 350. The electron injection layer may contact (e.g., directly contact) the second electrode 350.

The electron injection layer may have a structure consisting of a single material, a structure consisting of a layer including different materials, or a structure including multiple layers including different materials.

The electron injection layer may include an alkali metal, an alkali earth metal, a rare earth metal, an alkali metal-containing compound, an alkali earth metal-containing compound, a rare earth metal-containing compound, an alkali metal complex, an alkali earth metal complex, a rare earth metal complex, or any combination thereof.

The alkali metal may include Li, Na, K, Rb, Cs, or any combination thereof. The alkali earth metal may include Mg, Ca, Sr, Ba, or any combination thereof. The rare earth metal may include Sc, Y, Ce, Tb, Yb, Gd, or any combination thereof.

The alkali metal-containing compound, the alkali earth metal-containing compound, and the rare earth metal-containing compound may each include an oxide, a halide (for example, a fluoride, a chloride, a bromide, or an iodide), or a telluride of each of the alkali metal, the alkali earth metal, and the rare earth metal, or any combination thereof

The alkali metal-containing compound may include an alkali metal oxide such as Li₂O, Cs₂O, or K₂O, an alkali metal halide such as LiF, NaF, CsF, KF, LiI, NaI, CsI, or KI, or any combination thereof. The alkali earth metal-containing compound may include an alkaline earth metal compound such as BaO, SrO, CaO, BaxSr₁₋ₓO, wherein x is a real number satisfying 0<x<1, or BaxCa₁₋ₓO, wherein x is a real number satisfying 0<x<1. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkali earth metal complex, and the rare earth metal complex may include: an alkali metal ion, an alkali earth metal ion, or a rare earth metal ion as described above; and a ligand bonded to a metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzoimidazole, a hydroxyphenylbenzothiazole, a bipyridine, a phenanthroline, a cyclopentadiene, or any combination thereof).

In an embodiment, the electron injection layer may consist of an alkali metal, an alkali earth metal, a rare earth metal, an alkali metal-containing compound, an alkali earth metal-containing compound, a rare earth metal-containing compound, an alkali metal complex, an alkali earth metal complex, a rare earth metal complex, or any combination thereof as described above. In another embodiment, the electron injection layer may further include an organic material (for example, the compound represented by Formula 601).

According to an embodiment, the electron injection layer may consist of an alkali metal-containing compound (for example, an alkali metal halide); or the electron injection layer may consist of an alkali metal-containing compound (for example, an alkali metal halide), and an alkali metal, an alkali earth metal, a rare earth metal, or any combination thereof. For example, the electron injection layer may be a KI:Yb co-deposition layer, a RbI:Yb co-deposition layer, a LiF:Yb co-deposition layer, or the like.

When the electron injection layer further includes an organic material, an alkali metal, an alkali earth metal, a rare earth metal, an alkali metal-containing compound, an alkali earth metal-containing compound, a rare earth metal-containing compound, an alkali metal complex, an alkali earth metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer satisfies any of the ranges described above, satisfactory electron injection characteristics may be obtained without a substantial increase in driving voltage.

### [Second Electrode 350]

The second electrode 350 may be disposed on the interlayer 330 as described above. The second electrode 350 may be a cathode, which is an electron injection electrode. When the second electrode 350 is a cathode, the second electrode 350 may include a material having a low-work function, such as a metal, an alloy, an electrically conductive compound, or any combination thereof.

The second electrode 350 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 350 may be a transmissive electrode, a semi-transmissive electrode, or a reflective electrode.

The second electrode 350 may have a single-layered structure or a multi-layered structure.

### [Optical Member]

The quantum dot may be used in various optical members. Thus, according to an embodiment, an optical member may include the quantum dot.

In an embodiment, the optical member may be a light control means.

According to another embodiment, the optical member may be a color filter, a color conversion member, a capping layer, a light extraction efficiency enhancing layer, an optional light absorption layer, or a polarizing layer.

### [Electronic Apparatus]

The quantum dot may be used in various electronic apparatuses. According to an embodiment, an electronic apparatus may include the quantum dot.

According to an embodiment, an electronic apparatus may include a light source, and a color conversion member disposed on a path of light emitted from the light source, wherein the color conversion member may include the quantum dot.

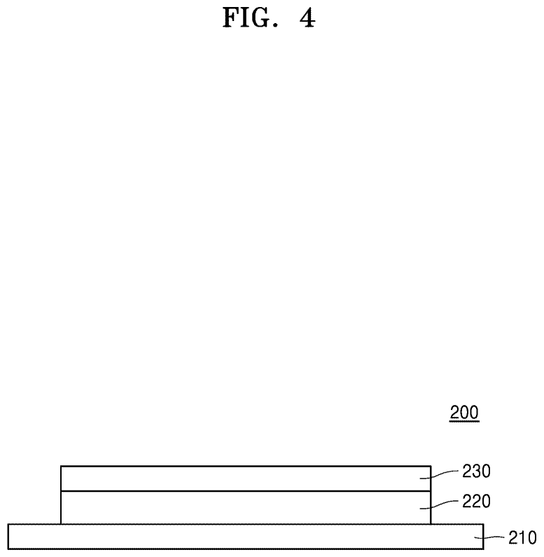

### [Description of FIG. 4]

FIG. 4 is a schematic cross-sectional view of an electronic apparatus 200 according to an embodiment. The electronic apparatus 200 of FIG. 4 may include a substrate 210, a light source 220 disposed on the substrate, and a color conversion member 230 disposed on the light source 220.

For example, the light source 220 may be a back light unit (BLU) used in a liquid crystal display (LCD), a fluorescent lamp, a light-emitting device, an organic light-emitting device, or a quantum dot light-emitting device (QLED), or any combination thereof. The color conversion member 230 may be disposed in at least one traveling direction of light emitted from the light source 220.

At least one area of the color conversion member 230 of the electronic apparatus 200 may include the quantum dot, and the area may absorb light emitted from the light source 220 to emit green light having a maximum emission wavelength in a range of about 500 nm to about 650 nm.

While the color conversion member 230 may be disposed in at least one traveling direction of light emitted from the light source 220, embodiments do not exclude cases where other elements may be further included between the color conversion member 230 and the light source 220.

For example, a polarizing plate, a liquid crystal layer, a light guide plate, a diffusion plate, a prism sheet, a microlens sheet, a luminance enhancement sheet, a reflective film, a color filter, or any combination thereof may be further included between the light source 220 and the color conversion member 230.

In another example, a polarizing plate, a liquid crystal layer, a light guide plate, a diffusion plate, a prism sheet, a microlens sheet, a luminance enhancement sheet, a reflective film, a color filter, or any combination thereof may be further included on the color conversion member 230.

The electronic apparatus 200 shown in FIG. 4 may be an example of an apparatus according to an embodiment, may have various forms according to the related art, and may additionally include various components of the related art for this purpose.

According to another embodiment, the electronic apparatus 200 may have a structure in which a light source, a light guide plate, a color conversion member, a first polarizing plate, a liquid crystal layer, a color filter, and a second polarizing plate are disposed in this stated order, but embodiments are not limited thereto.

According to another embodiment, the electronic apparatus 200 may have a structure in which a light source, a light guide plate, a first polarizing plate, a liquid crystal layer, a second polarizing plate, and a color conversion member are disposed in this stated order, but embodiments are not limited thereto.

In the above described embodiments, the color filter may include a pigment or a dye. In the above described embodiments, one of the first polarizing plate and the second polarizing plate may be a vertical polarizing plate, and the other may be a horizontal polarizing plate.

The quantum dot and the light-emitting device including the quantum dot may be included in various electronic apparatuses. For example, an electronic apparatus including the quantum dot and the light-emitting device including the quantum dot may be a light-emitting apparatus, an authentication apparatus, or the like.

In addition to the light-emitting device 300, the electronic apparatus (for example, a light-emitting apparatus) may further include a color filter, a color conversion layer, or a color filter and a color conversion layer. The color filter and/or the color conversion layer may be disposed in at least one traveling direction of light emitted from the light-emitting device 300. For example, light emitted from the light-emitting device 300 may be green light, blue light, or white light. The light-emitting device 300 may be the same as described herein. According to an embodiment, the color conversion layer may include a quantum dot. The quantum dot may be, for example, a quantum dot as described herein.

The electronic apparatus may further include a thin film transistor in addition to the light-emitting device 300 described above. The thin film transistor may include a source electrode, a drain electrode, and an active layer, and any one of the source electrode and the drain electrode may be electrically connected to any one of a first electrode 310 and a second electrode 350 of the light-emitting device 300.

The thin film transistor may further include a gate electrode, a gate insulating film, and the like.

The active layer may include crystalline silicon, amorphous silicon, an organic semiconductor, an oxide semiconductor, or the like.

The electronic apparatus may further include a sealing portion that seals the light-emitting device 300. The sealing portion may be disposed between the color filter and/or color conversion layer and the light-emitting device 300. The sealing portion may allow light from the light-emitting device 300 to be extracted to the outside and may prevent ambient air and moisture from penetrating into the light-emitting device 300. The sealing portion may be a sealing substrate including a transparent glass substrate or a plastic substrate. The sealing portion may be a thin film encapsulation layer including one or more organic layers and/or one or more inorganic layers. When the sealing portion is a thin film encapsulation layer, the electronic apparatus may be flexible.

Various functional layers may be further included on the sealing portion, in addition to the color filter and/or the color conversion layer, according to a use of the electronic apparatus. Examples of functional layers may include a touch screen layer, a polarizing layer, and the like. The touch screen layer may be a pressure-sensitive touch screen layer, a capacitive touch screen layer, or an infrared touch screen layer.

The authentication apparatus may be, for example, a biometric authentication apparatus configured to authenticate an individual by using biometric information of a living body (for example, fingertips, pupils, or the like).

The authentication apparatus may further include a biometric information collection means, in addition to the light-emitting device 300 described above.

The electronic apparatus may be applied to various displays, light sources, lights, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement apparatuses, pulse wave measurement apparatuses, electrocardiogram displays, ultrasonic diagnostic apparatuses, or endoscope displays), fish finders, various measuring instruments, meters (for example, meters for a vehicle, an aircraft, and a vessel), projectors, and the like.

### [Electronic Equipment]

The quantum dot and the light-emitting device including the quantum dot may be included in a variety of electronic equipment.

For example, an electronic equipment including the light-emitting device may be a flat panel display, a curved display, a computer monitor, a medical monitor, a television, a billboard, an indoor light, an outdoor light, a signal light, a head-up display (HUD), a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro-display, a three-dimensional (3D) display, a virtual reality display, an augmented reality display, a vehicle, a video wall with multiple displays tiled together, a theater screen, a stadium screen, a phototherapy device, or a signboard.

Since the light-emitting device has excellent luminous efficiency, long-lifetime effect, or the like, the electronic equipment including the light-emitting device may have characteristics such as high luminance, high resolution, and low power consumption.

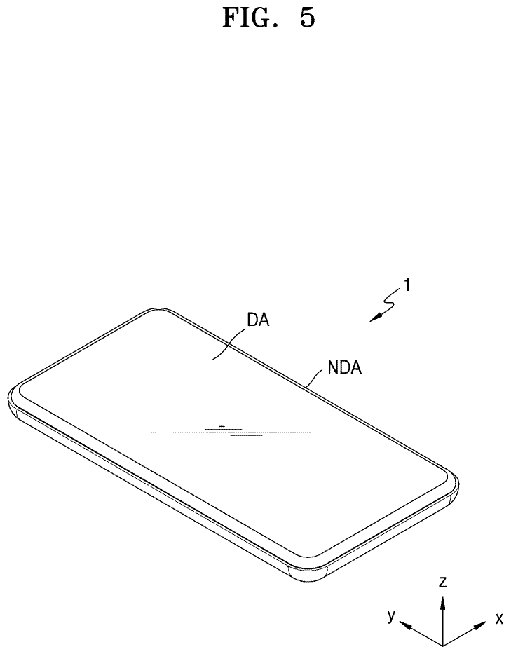

### [Description of FIG. 5]

FIG. 5 is a schematic perspective view of an electronic equipment 1 including a light-emitting device according to an embodiment.

The electronic equipment 1, which may be an apparatus that displays a moving image or a still image, may not only be a portable electronic equipment such as a mobile phone, a smartphone, a tablet computer, a mobile communication terminal, an electronic notebook, an e-book, a portable multimedia player (PMP), a navigation system, or an ultra-mobile personal computer (UMPC), but may also be various products such as a television, a laptop, a monitor, a billboard, or an Internet of things (IoT) device. The electronic equipment 1 may be any such product as described above or a part thereof.

In an embodiment, the electronic equipment 1 may be a wearable device such as a smart watch, a watch phone, a glasses-type display, or a head mounted display (HMD), or a part thereof. However, embodiments are not limited thereto.

In an embodiment, examples of the electronic equipment 1 may include a dashboard of a vehicle, a center information display (CID) disposed on a center fascia or dashboard of a vehicle, a room mirror display that replaces a side mirror of a vehicle, an entertainment display for a rear seat of a vehicle or a display disposed on the back of a front sea, an HUD installed at the front of a vehicle or projected on a front window glass, or a computer-generated hologram augmented reality head-up display (CGH AR HUD). For convenience of description, FIG. 5 illustrates an embodiment in which the electronic equipment 1 is a smartphone.

The electronic equipment 1 may include a display area DA and a non-display area NDA outside the display area DA. A display apparatus may implement an image through a two-dimensional array of pixels arranged in the display area DA.

The non-display area NDA may be an area in which an image is not displayed and may surround (e.g., entirely surround) the display area DA. Drivers or the like, which provide electrical signals or power to display devices that are disposed in the display area DA, may be disposed in the non-display area NDA. A pad, which is an area to which an electronic device, a printed circuit board, and the like may be electrically connected, may be disposed in the non-display area NDA.

In the electronic equipment 1, a length in an x-axis direction may be different from a length in a y-axis direction. For example, as shown in FIG. 5, a length in the x-axis direction may be shorter than a length in the y-axis direction. As another example, a length in the x-axis direction may be equal to a length in the y-axis direction. As another example, a length in the x-axis direction may be longer than a length in the y-axis direction.

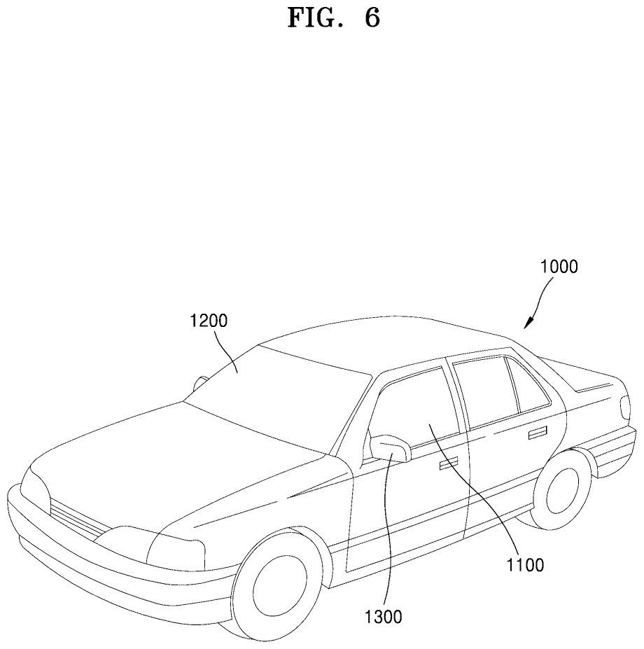

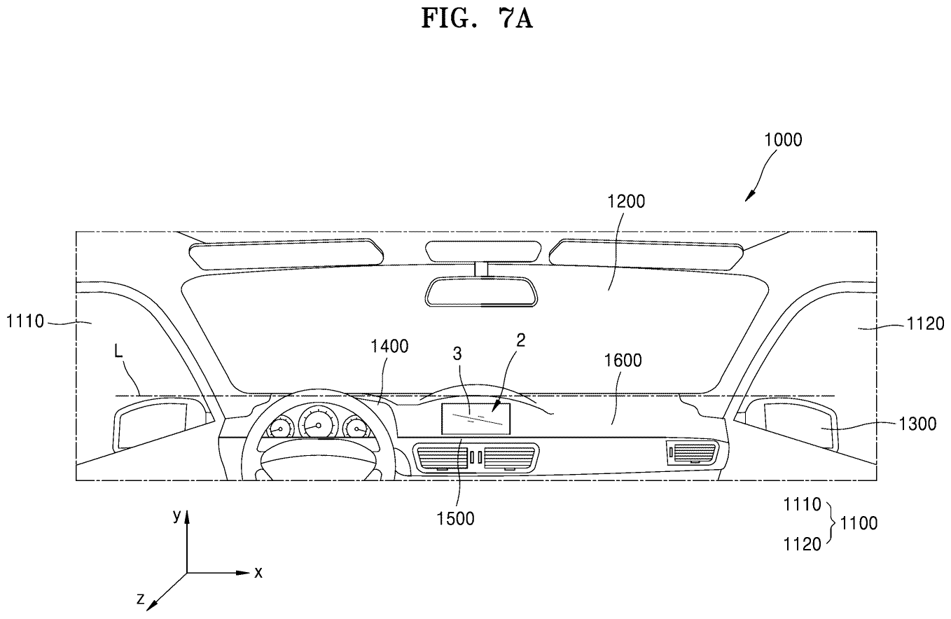

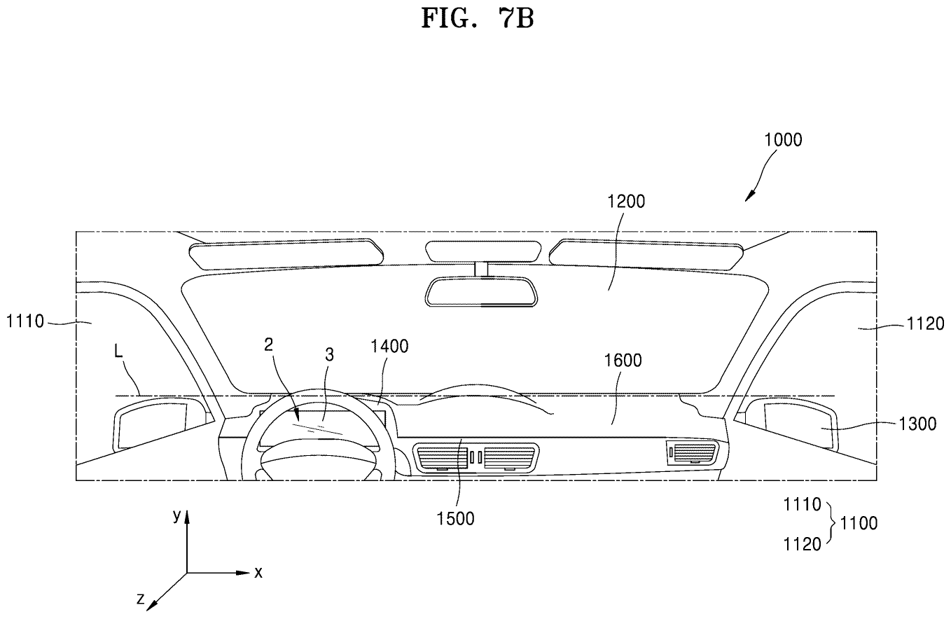

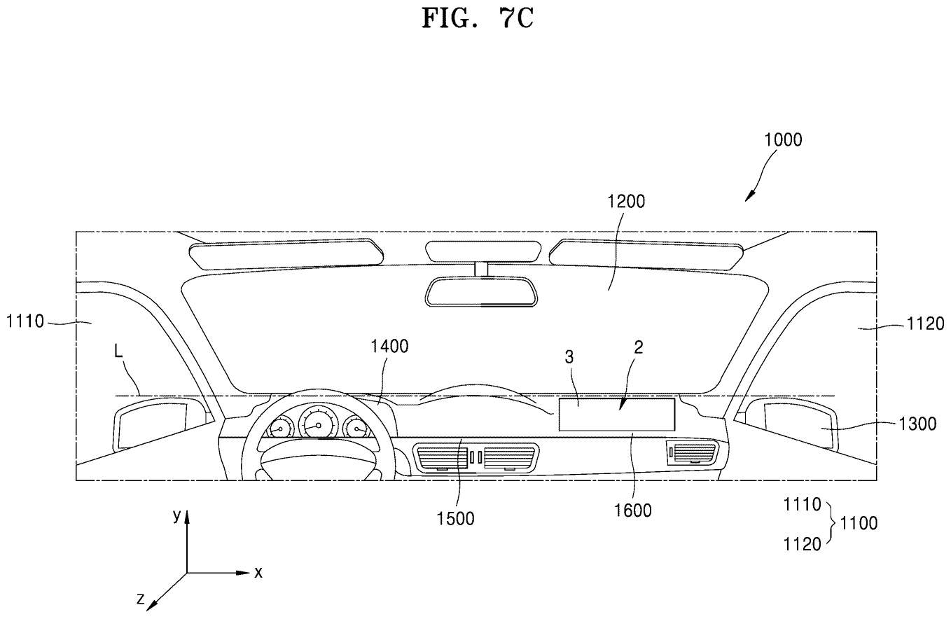

### [Description of FIGS. 6 and 7A to 7C]

FIG. 6 is a schematic perspective view of an exterior of a vehicle 1000 as an electronic equipment including a light-emitting device according to an embodiment. FIGS. 7A to 7C are each a schematic view of an interior of the vehicle 1000 according to embodiments.

Referring to FIGS. 6, 7A, 7B, and 7C, embodiments of the vehicle 1000 may include various apparatuses that move a subject to be transported, such as a person, an object, or an animal, from a departure point to a destination. Examples of a vehicle 1000 may include a vehicle traveling on a road or a track, a vessel moving over a sea or a river, an airplane flying in the sky using the action of air, and the like.

The vehicle 1000 may travel on a road or a track. The vehicle 1000 may move in a selectable direction according to the rotation of at least one wheel. Examples of the vehicle 1000 may include a three-wheeled or four-wheeled vehicle, a construction machine, a two-wheeled vehicle, a prime mover apparatus, a bicycle, and a train traveling on a track.

The vehicle 1000 may include a body having an interior and an exterior, and a chassis that is a portion excluding the body in which mechanical apparatuses necessary for driving are installed. The exterior of the body may include a front panel, a bonnet, a roof panel, a rear panel, a trunk, a pillar provided at a boundary between doors, and the like. The chassis of the vehicle 1000 may include a power generating apparatus, a power transmitting apparatus, a driving apparatus, a steering apparatus, a braking apparatus, a suspension apparatus, a transmission apparatus, a fuel apparatus, front, rear, left, and right wheels, and the like.

The vehicle 1000 may include a side window glass 1100, a front window glass 1200, a side mirror 1300, a cluster 1400, a center fascia 1500, a passenger seat dashboard 1600, and a display apparatus 2.

The side window glass 1100 and the front window glass 1200 may be partitioned by a pillar disposed between the side window glass 1100 and the front window glass 1200.

The side window glass 1100 may be installed on a side of the vehicle 1000. In an embodiment, the side window glass 1100 may be installed on a door of the vehicle 1000. Multiple side window glasses 1100 may be provided and may face each other.

In an embodiment, the side window glasses 1100 may include a first side window glass 1110 and a second side window glass 1120. In an embodiment, the first side window glass 1110 may be positioned adjacent to the cluster 1400, and the second side window glass 1120 may be disposed adjacent to the passenger seat dashboard 1600.

In an embodiment, the side window glasses 1100 may be spaced apart from each other in an x direction or a−x direction. For example, the first side window glass 1110 and the second side window glass 1120 may be spaced apart from each other in the x direction or the −x direction. For example, a virtual straight line L connecting the side window glasses 1100 may extend in the x direction or the −x direction. For example, a virtual straight line L connecting the first side window glass 1110 and the second side window glass 1120 may extend in the x direction or the −x direction.

The front window glass 1200 may be installed in the front of the vehicle 1000. The front window glass 1200 may be disposed between the side window glasses 1100 facing each other.

The side mirror 1300 may provide a rearward field of view of the vehicle 1000. The side mirror 1300 may be installed on the exterior of the body. In an embodiment, multiple side mirrors 1300 may be provided. For example, one of the side mirrors 1300 may be positioned outside the first side window glass 1110, and another one of the side mirrors 1300 may be positioned outside the second side window glass 1120.

The cluster 1400 may be positioned in front of a steering wheel. The cluster 1400 may be equipped with a tachometer, a speedometer, a coolant temperature gauge, a fuel gauge turn indicator, a high beam indicator, a warning light, a seat belt warning light, an odometer, a tachograph, an automatic transmission selector indicator, a door open warning light, an engine oil warning light, and/or a low fuel warning light.

The center fascia 1500 may include a control panel on which buttons for adjusting an audio apparatus, an air conditioning apparatus, and a seat heater are disposed. The center fascia 1500 may be disposed at a side of the cluster 1400.

The passenger seat dashboard 1600 may be spaced apart from the cluster 1400, and the center fascia 1500 may be disposed between the cluster 1400 and the passenger seat dashboard 1600. In an embodiment, the cluster 1400 may be disposed to correspond to a driver seat (not shown), and the passenger seat dashboard 1600 may be disposed to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display apparatus 2 may include a display panel 3, and the display panel 3 may display an image. The display apparatus 2 may be disposed inside the vehicle 1000. In an embodiment, the display apparatus 2 may be positioned between the side window glasses 1100 facing each other. The display apparatus 2 may be disposed on at least one of the cluster 1400, the center fascia 1500, and the passenger seat dashboard 1600.

The display apparatus 2 may include an organic light-emitting display, an inorganic light-emitting display, a quantum dot display, or the like. Hereinafter, an organic light-emitting display including a light-emitting device according to an embodiment will be described as an example of the display apparatus 2. However, various types of display apparatuses as described above may be used in embodiments.

Referring to FIG. 7A, the display apparatus 2 may be disposed on the center fascia 1500. In an embodiment, the display apparatus 2 may display navigation information. In an embodiment, the display apparatus 2 may display audio information, video information, or information about a vehicle setting.

Referring to FIG. 7B, the display apparatus 2 may be disposed on the cluster 1400. In an embodiment, the cluster 1400 may display driving information or the like through the display apparatus 2. For example, the cluster 1400 may digitally implement display driving information and the like. The digital cluster 1400 may display vehicle information and driving information as images. For example, a needle and a gauge of a tachometer and various warning lights or icons may be displayed through a digital signal.

Referring to FIG. 7C, the display apparatus 2 may be disposed on the passenger seat dashboard 1600. The display apparatus 2 may be embedded in the passenger seat dashboard 1600 or positioned on the passenger seat dashboard 1600.

In an embodiment, the display apparatus 2 positioned on the passenger seat dashboard 1600 may display an image that is related to information displayed on the cluster 1400 and/or information displayed on the center fascia 1500. In another embodiment, the display apparatus 2 positioned on the passenger seat dashboard 1600 may display information that is different from the information displayed on the cluster 1400 and/or the information displayed on the center fascia 1500.

### Definitions of Terms

As used herein, the term “C₃-C₆ carbocyclic group” may be a cyclic group having 3 to 60 carbon atoms and consisting only of carbon as a ring-forming atom, and the term “C₁-C₆₀ heterocyclic group” may be a cyclic group having 1 to 60 carbon atoms and further including at least one heteroatom as a ring-forming atom, in addition to carbon atoms. The C₃-C₆₀ carbocyclic group and the C₁-C₆₀ heterocyclic group may each be a monocyclic group having one ring or a polycyclic group in which two or more rings are condensed with each other. For example, the C₁-C₆₀ heterocyclic group may have 3 to 61 ring-forming atoms.

As used herein, the term “cyclic group” may be a C₃-C₆₀ carbocyclic group or a C₁-C₆₀ heterocyclic group.

As used herein, the term “π electron-rich C₃-C₆₀ cyclic group” may be a cyclic group that has 3 to 60 carbon atoms and may not include *—N═*′ as a ring-forming moiety, and the term “π electron-deficient nitrogen-containing C₁-C₆₀ cyclic group” may be a heterocyclic group that has 1 to 60 carbon atoms and may include *—N═*′ as a ring-forming moiety.

In embodiments,
a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are fused with each other, or a group in which one or more T2 groups and one or more T1 groups are fused with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),
a π electron-rich C₃-C₆₀ cyclic group may be a T1 group, a group in which two or more T1 groups are fused with each other, a T3 group, a group in which two or more T3 groups are fused with each other, or a group in which one or more T3 groups and one or more T1 groups are fused with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, or a benzothienodibenzothiophene group), and
a π electron-deficient nitrogen-containing C₁-C₆₀ cyclic group may be a T4 group, ii) a group in which two or more T4 groups are fused with each other, a group in which one or more T4 groups and one or more T1 groups are fused with each other, a group in which one or more T4 groups and one or more T3 groups are fused with each other, or a group in which one or more T4 groups, one or more T1 groups, and one or more T3 groups are fused with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group).

A T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group.

A T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

A T3 group may be a furan group, a thiophene group, a 1H-pyrrole group, a silole group, or a borole group.

A T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

As used herein, the term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” may each be a group condensed to any cyclic group, a monovalent group, or a multivalent group (for example, a divalent group, a trivalent group, or a tetravalent group) according to a structure of a formula in which the term is used. For example, a “benzene group” may be a benzo group, a phenyl group, a phenylene group, or the like, which may be understood by those skilled in the art according to a structure of a formula including the “benzene group”.

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₁-C₆₀ arylene group, a C₁-C₆₀ heteroarylene group, a divalent non-aromatic condensed polycyclic group, and a divalent non-aromatic condensed heteropolycyclic group.

As used herein, the term “C₁-C₆₀ alkyl group” may be a linear or branched monovalent aliphatic hydrocarbon group having 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. As used herein, the term “C₁-C₆₀ alkylene group” may be a divalent group having a same structure as the C₁-C₆₀ alkyl group.

As used herein, the term “C₂-C₆₀ alkenyl group” may be a monovalent hydrocarbon group including one or more carbon-carbon double bonds in the middle or at a terminus of a C₂-C₆₀ alkyl group, and examples thereof may include an ethenyl group, a propenyl group, a butenyl group, and the like. As used herein, the term “C₂-C₆₀ alkenyl group” may be a divalent group having a same structure as the C₂-C₆₀ alkenyl group.

As used herein, the term “C₂-C₆₀ alkynyl group” may be a monovalent hydrocarbon group including one or more carbon-carbon triple bonds in the middle or at a terminus of a C₂-C₆₀ alkyl group, and examples thereof may include an ethynyl group, a propynyl group, and the like. As used herein, the term “C₂-C₆₀ alkynylene group” may be a divalent group having a same structure as the C₂-C₆₀ alkynyl group.

As used herein, the term “C₁-C₆₀ alkoxy group” may be a monovalent group having a formula of —O(A₁₀₁), wherein A₁₀₁ may be a C₁-C₆₀ alkyl group, and examples thereof may include a methoxy group, an ethoxy group, an isopropyloxy group, and the like.

As used herein, the term “C₃-C₁₀ cycloalkyl group” may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, adamantanyl, a norbornanyl group (or, a bicyclo[2.2.1]heptyl group), a bicyclo[1.1.1]pentyl group, a bicyclo[2.1.1]hexyl group, a bicyclo[2.2.2]octyl group, and the like. As used herein, the term “C₃-C₁₀ cycloalkylene group” may be a divalent group having a same structure as the C₃-C₁₀ cycloalkyl group.

As used herein, the term “C₁-C₁₀ heterocycloalkyl group” may be a monovalent cyclic group having 1 to 10 carbon atoms and further including at least one heteroatom as a ring-forming atom in addition to carbon atoms, and examples thereof may include a 1,2,3,4-oxatriazolidinyl group, a tetrahydrofuranyl group, a tetrahydrothiophenyl group, and the like. As used herein, the term “C₁-C₁₀ heterocycloalkylene group” may be a divalent group having a same structure as the C₁-C₁₀ heterocycloalkyl group.

As used herein, the term “C₃-C₁₀ cycloalkenyl group” may be a monovalent cyclic group which has 3 to 10 carbon atoms and refers to a group having at least one carbon-carbon double bond in a cyclic structure thereof and not having aromaticity, and examples thereof may include a cyclopentenyl group, a cyclohexenyl group, a cycloheptenyl group, and the like. As used herein, the term “C₃-C₁₀ cycloalkenylene group” may be a divalent group having a same structure as the C₃-C₁₀ cycloalkenyl group.

As used herein, the term “C₁-C₁₀ heterocycloalkenyl group” may be a monovalent cyclic group which has 1 to 10 carbon atoms, further includes at least one heteroatom as a ring-forming atom in addition to carbon atoms, and has at least one double bond in a cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. As used herein, the term “C₁-C₁₀ heterocycloalkenylene group” may be a divalent group having a same structure as the C₁-C₁₀ heterocycloalkenyl group.

As used herein, the term “C₆-C₆₀ aryl group” may be a monovalent group having a carbocyclic aromatic system which has 6 to 60 carbon atoms, and the term “C₆-C₆₀ arylene group” may be a divalent group having a carbocyclic aromatic system which has 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group include two or more rings, the respective two or more rings may be condensed with each other.

As used herein, the term “C₁-C₆₀ heteroaryl group” may be a monovalent group further including at least one heteroatom as a ring-forming atom in addition to carbon atoms and having a heterocyclic aromatic system which has 1 to 60 carbon atoms. The term “C₁-C₆₀ heteroarylene group” may be a divalent group further including at least one heteroatom as a ring-forming atom in addition to carbon atoms and having a heterocyclic aromatic system which has 1 to 60 carbon atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group include two or more rings, the respective two or more rings may be condensed with each other.

As used herein, the term “monovalent non-aromatic condensed polycyclic group” may be a monovalent group (for example, having 8 to 60 carbon atoms) in which two or more rings are condensed with each other, which includes only carbon as a ring-forming atom, and has no aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, an indenoanthracenyl group, and the like. As used herein, the term “divalent non-aromatic condensed polycyclic group” may be a divalent group having a same structure as the monovalent non-aromatic condensed polycyclic group.

As used herein, the term “monovalent non-aromatic condensed heteropolycyclic group” may be a monovalent group (for example, having 1 to 60 carbon atoms) in which two or more rings are condensed with each other, which further includes at least one heteroatom as a ring-forming atom in addition to carbon atoms, and has no aromaticity in its molecular structure when considered as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. As used herein, the term “divalent non-aromatic condensed heteropolycyclic group” may be a divalent group having a same structure as the monovalent non-aromatic condensed heteropolycyclic group.

As used herein, the term “C₆-C₆₀ aryloxy group” may be a group represented by —O(A₁₀₂), wherein A₁₀₂ may be a C₆-C₆₀ aryl group, and the term “C₆-C₆₀ arylthio group” may be a group represented by —S(A₁₀₃), wherein A₁₀₃ may be a C₆-C₆₀ aryl group.

As used herein, the term “C₇-C₆₀ arylalkyl group” may be a group represented by -(A₁₀₄)(A₁₀₅), wherein A₁₀₄ may be a C₁-C₅₄ alkylene group and A₁₀₅ may be a C₆-C₅₉ aryl group, and the term “C₂-C₆₀ heteroarylalkyl group” may be a group represented by -(A₁₀₆)(A₁₀₇), wherein A₁₀₆ may be a C₁-C₅₉ alkylene group and A₁₀₇ may be a C₁-C₅₉ heteroaryl group.

In the specification, the term “R₁₀ₐ” may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

As used herein, the term “heteroatom” may be any atom other than a carbon atom or a hydrogen atom. Examples of a heteroatom may include O, S, N, P, Si, B, Ge, Se, and any combination thereof.

As used herein, examples of a “transition metal” may be hafnium (Hf), tantalum (Ta), tungsten (W), rhenium (Re), osmium (Os), iridium (Ir), platinum (Pt), gold (Au), and the like.

As used herein, the term “Ph” refers to a phenyl group, the term “Me” refers to a methyl group, the term “Et” refers to an ethyl group, the terms “ter-Bu” and “Bu^{t}” each refer to a tert-butyl group, and the term “OMe” refers to a methoxy group.

As used herein, the term “biphenyl group” may be a “phenyl group substituted with a phenyl group”. For example, the “biphenyl group” may be a substituted phenyl group having a C₆-C₆₀ aryl group as a substituent.

As used herein, the term “terphenyl group” may be a “phenyl group substituted with a biphenyl group”. For example, the “terphenyl group” may be a substituted phenyl group of which a substituent is a C₆-C₆₀ aryl group substituted with a C₆-C₆₀ aryl group.

As used herein, unless otherwise defined, the symbols “* and *′” each refer to a bonding site with an adjacent atom in a corresponding formula or moiety.

Hereinafter, a quantum dot according to an embodiment will be described in more detail with respect to the Comparative Test Examples and Test Examples.

### COMPARATIVE TEST EXAMPLES AND TEST EXAMPLES

### COMPARATIVE TEST EXAMPLE 1: SYNTHESIS OF AGIN_{0.5}GA_{0.5}S QUANTUM DOTS

(Synthesis of AgIn_{0.5}Ga_{0.5}S Core)

0.2 mmol of AgI, 0.5 mmol of InI₃, and 0.5 mmol of Gals were put into a three-neck flask, mixed with 5 ml of OLA and 5 ml of 1-octadecene (ODE), degassed and stirred at a temperature of 120° C. for 30 minutes to prepare a reaction solution.

1.0 mmol of sulfur (S)-OLA and 0.2 mmol of 1-dodecanethiol were added to the reaction solution in a nitrogen (N₂) atmosphere, a temperature was raised to 230° C. maintained for 1 hour, and cooled to room temperature to synthesize AgIn_{0.5}Ga_{0.5}S quantum dots.

The synthesized AgIn_{0.5}Ga_{0.5}S quantum dots were diluted in toluene and precipitated with ethanol for purification.

### Comparative Test Example 2: Synthesis of AgIn_{0.5}Ga_{0.5}S/ZnS Quantum Dots

(Synthesis of AgIn_{0.5}Ga_{0.5}S Core)

A AgIn_{0.5}Ga_{0.5}S core was synthesized in the same manner as in Comparative Test Example 1.

### (Synthesis of ZnS Shell)

After 1.0 mmol of purified AgIn_{0.5}Ga_{0.5}S quantum dots were dispersed in toluene, 1.0 mmol of S-OLA was mixed and degassed at a temperature of 120° C. 1.6 mmol of zinc acetate (Zn(OA)₂) and 2.27 mmol of trioctylphosphine sulfide (TOP-S) were added and allowed to react at a temperature of 280° C. or more for 20 minutes to form a ZnS shell on a AgIn_{0.5}Ga_{0.5}S quantum dot core.

### Comparative Test Example 3: Synthesis of AgIn_{0.5}Ga_{0.5}S/CuIn_{0.1}Ga_{0.9}S/ZnS Quantum Dots

(Synthesis of AgIn_{0.5}Ga_{0.5}S Core)

AgIn_{0.5}Ga_{0.5}S core was synthesized in the same manner as in Comparative Test Example 1.

(Synthesis of CuIn_{0.1}Ga_{0.9}S Shell)

After 1.0 mmol of purified AgIn_{0.5}Ga_{0.5}S quantum dots were dispersed in toluene, 0.5 mmol of CuI, 1.0 mmol of InI₃, and 9.0 mmol of GaI₃ were put into a three-neck flask, mixed with 5 ml of OLA and 5 ml of ODE, stirred and degassed at a temperature of 120° C. for 30 minutes to prepare a reaction solution.

10 mmol of S-OLA and 3 mmol of 1-dodecanethiol were added to the reaction solution in a nitrogen (N₂) atmosphere, a temperature was raised to 230° C., maintained for 2 hour, and cooled to room temperature to synthesize a CuIn_{0.1}Ga_{0.9}S shell on a AgIn_{0.5}Ga_{0.5}S quantum dot core.

### (Synthesis of ZnS Shell)

A ZnS shell was synthesized on a core/shell of AgIn_{0.5}Ga_{0.5}S/CuIn_{0.1}Ga_{0.9}S in the same manner as the synthesis of a ZnS shell in Comparative Test Example 1.

### Test Example 1: Synthesis of AgIn_{0.5}Ga_{0.5}S/CuIn_{0.3}Ga_{0.7}S/ZnS Quantum Dots

AgIn_{0.5}Ga_{0.5}S/CuIn_{0.3}Ga_{0.7}S/ZnS quantum dots were synthesized in the same manner as the synthesis of AgIn_{0.5}Ga_{0.5}S/CuIn_{0.1}Ga_{0.9}S/ZnS quantum dots in Comparative Test Example 3, except that, when a CuIn_{0.3}Ga_{0.7}S shell was synthesized, CuI, InI, and GaI were respectively used in amounts of 0.5 mmol, 3.0 mmol, and 7.0 mmol instead of 0.5 mmol, 1.0 mmol, and 9.0 mmol.

### Test Example 2: Synthesis of AgIn_{0.5}Ga_{0.5}S/CuIn_{0.6}Ga_{0.4}S/ZnS Quantum Dots

AgIn_{0.5}Ga_{0.5}S/CuIn_{0.6}Ga_{0.4}S/ZnS quantum dots were synthesized in the same manner as the synthesis of AgIn_{0.5}Ga_{0.5}S/CuIn_{0.1}Ga_{0.9}S/ZnS quantum dots in Comparative Test Example 3, except that, when a CuIn_{0.6}Ga_{0.4}S shell was synthesized, CuI, InI, and GaI were respectively used in amounts of 0.5 mmol, 6.0 mmol, and 4.0 mmol instead of 0.5 mmol, 1.0 mmol, and 9.0 mmol.

### Comparative Test Example 4: Synthesis of AgIn_{0.9}Ga_{0.1}S Quantum Dots

(Synthesis of AgIn_{0.9}Ga_{0.1}S Core)

A AgIn_{0.9}Ga_{0.1}S core was synthesized in the same manner as the synthesis of a AgIn_{0.5}Ga_{0.5}S core of Comparative Test Example 1, except that AgI, InI, and GaI were respectively used in amounts of 0.2 mmol, 0.9 mmol, and 0.1 mmol instead of 0.2 mmol, 0.5 mmol, and 0.5 mmol.

### Comparative Test Example 5: Synthesis of AgIn_{0.9}Ga_{0.1}S/ZnS Quantum Dots

AgIn_{0.9}Ga_{0.1}S/ZnS quantum dots were synthesized in the same manner as the synthesis of quantum dots in Comparative Test Example 2, except that, when a AgIn_{0.9}Ga_{0.1}S core was synthesized, AgI, InI, and GaI were respectively used in amounts of 0.2 mmol, 0.9 mmol, and 0.1 mmol instead of 0.2 mmol, 0.5 mmol, and 0.5 mmol.

### Comparative Test Example 6: Synthesis of AgIn_{0.9}Ga_{0.1}S/CuIn_{0.3}Ga_{0.7}S/ZnS Quantum Dots

AgIn_{0.9}Ga_{0.1}S/CuIn_{0.3}Ga_{0.7}S/ZnS quantum dots were synthesized in the same manner as the synthesis of quantum dots in Test Example 1, except that, when a AgIn_{0.9}Ga_{0.1}S core was synthesized, AgI, InI, and GaI were respectively used in amounts of 0.2 mmol, 0.9 mmol, and 0.1 mmol instead of 0.2 mmol, 0.5 mmol, and 0.5 mmol, and when a CuIn_{0.3}Ga_{0.7}S shell was synthesized, CuI, InI, and GaI were respectively used in amounts of 0.5 mmol, 3.0 mmol, and 7.0 mmol instead of 0.5 mmol, 1.0 mmol, and 9.0 mmol.

### Test Example 3: Synthesis of AgIn_{0.9}Ga_{0.1}S/CuIn_{0.6}Ga_{0.4}S/ZnS Quantum Dots

AgIn_{0.9}Ga_{0.1}S/CuIn_{0.6}Ga_{0.4}S/ZnS quantum dots were synthesized in the same manner as the synthesis of quantum dots in Test Example 2, except that, when a AgIn_{0.9}Ga_{0.1}S core was synthesized, AgI, InI, and GaI were respectively used in amounts of 0.2 mmol, 0.9 mmol, and 0.1 mmol instead of 0.2 mmol, 0.5 mmol, and 0.5 mmol, and when a CuIn_{0.6}Ga_{0.4}S shell was synthesized, CuI, InI, and GaI were respectively used in amounts of 0.5 mmol, 6.0 mmol, and 4.0 mmol instead of 0.5 mmol, 1.0 mmol, and 9.0 mmol.

### Test Example 4: Synthesis of AgIn_{0.9}Ga_{0.1}S/CuIn_{0.8}Ga_{0.2}S/ZnS Quantum Dots

AgIn_{0.9}Ga_{0.1}S/CuIn_{0.8}Ga_{0.2}S/ZnS quantum dots were synthesized in the same manner as the synthesis of quantum dots in Test Example 3, except that, when a CuIn_{0.8}Ga_{0.2}S shell was synthesized, CuI, InI, and GaI were respectively used in amounts of 0.5 mmol, 8.0 mmol, and 2.0 mmol instead of 0.5 mmol, 1.0 mmol, and 9.0 mmol.

### Evaluation Example: Evaluation of Quantum Dot PL Properties

For the quantum dots of Comparative Test Examples 1 to 6 and Test Examples 1 to 4, 0.2 ml of the quantum dots were dispersed in 2.8 ml of toluene in a quartz cuvette, and a PL spectrum and quantum yield of the quantum dots were measured. The PL spectrum was measured by using a PL spectrometer (FluoroMax manufactured by Horiba) and a UV-VIS spectrometer (Lambda 365+ manufactured by PerkinElmer, Inc.), and a maximum emission wavelength and a FWHM were obtained from PL spectrum. A wavelength of excitation light was 450 nm. A quantum yield was evaluated by using an absolute quantum yield measuring device (QE-2100 manufactured by Otsuka Electronics). A quantum yield retention rate is a value expressed as a percentage of a quantum yield after exposure of a solution with an optical density of 1.0 to blue light (460 nm) with 200 nits to a quantum yield before exposure of the solution to light.

The quantum dots of Comparative Test Examples 1 to 3, Test Example 1, and Test Example 2 emit light in a green region with a maximum emission wavelength in a range of about 500 nm to about 550 nm, and the quantum dots of Comparative Test Examples 4 to 6, Test Example 3, and Test Example 4 emit light in a blue region with a maximum emission wavelength in a range of about 610 nm to about 640 nm.

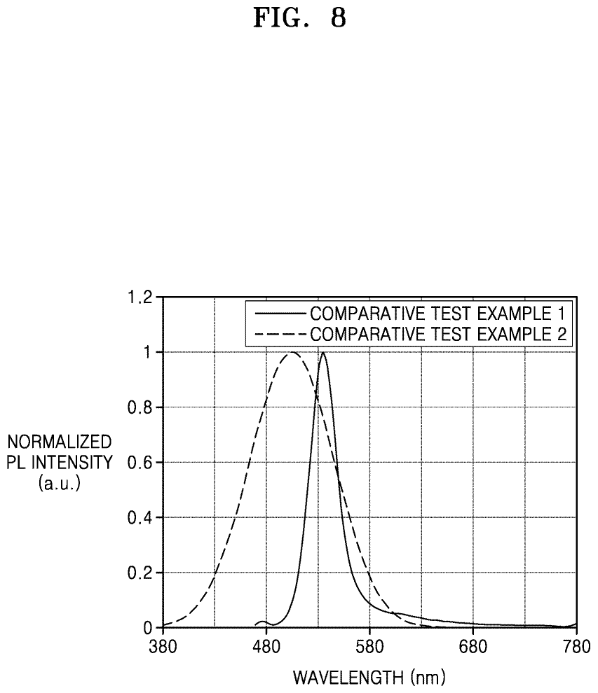

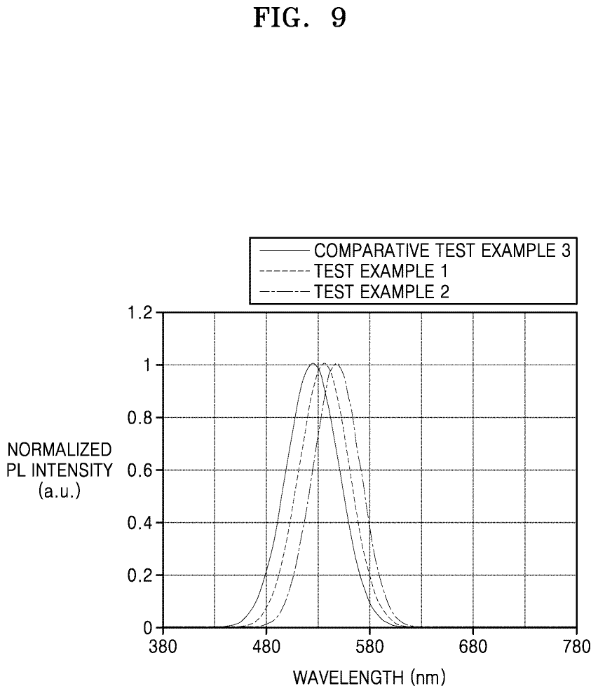

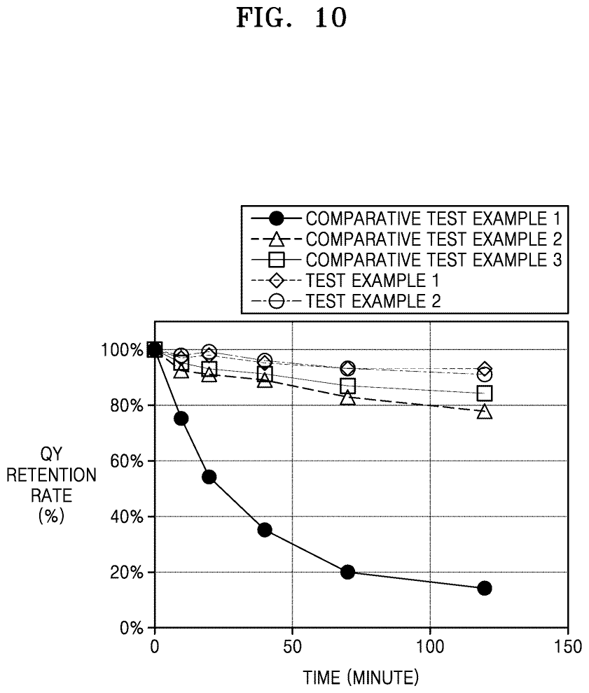

FIG. 8 is a graph showing PL spectra of the quantum dots prepared in Comparative Test Example 1 and Comparative Test Example 2. FIG. 9 is a graph showing PL spectra of the quantum dots prepared in Comparative Test Example 3, Test Example 1, and Test Example 2. FIG. 10 is a graph showing a quantum yield (QY) retention rate according to a light exposure time of the quantum dots of Comparative Test Examples 1 to 3, Test Example 1, and Test Example 2.

Table 2 is a table showing a maximum PL wavelength, a FWHM, a quantum yield, and a quantum yield retention rate after exposure to light for 2 hours of Comparative Test Examples 1 to 3, Test Example 1, and Test Example 2.

TABLE 2

| | Band gap | | | | |
|---|---|---|---|---|---|
| | energy | Maximum | | | Quantum |
| | difference | PL | | | yield |
| | between core | wavelength | FWHM | Quantum | retention |
| | and shell (eV) | (nm) | (nm) | yield (%) | rate (%) |
| Comparative Test Example 1 | — | 537 | 36 | 60 | 14 |
| (AgIn_{0.5}Ga_{0.5}S) | | | | | |
| Comparative Test Example 2 | — | 505 | 96 | 81 | 78 |
| (AgIn_{0.5}Ga_{0.5}S/ZnS) | | | | | |
| Comparative Test Example 3 | −0.1 | 525 | 60 | 84 | 84 |
| (AgIn_{0.5}Ga_{0.5}S/CuIn_{0.1}Ga_{0.9}S/ZnS) | | | | | |
| Test Example 1 | +0.1 | 536 | 57 | 88 | 93 |
| (AgIn_{0.5}Ga_{0.5}S/CuIn_{0.3}Ga_{0.7}S/ZnS) | | | | | |
| Test Example 2 | +0.4 | 548 | 55 | 91 | 91 |
| (AgIn_{0.5}Ga_{0.5}S/CuIn_{0.6}Ga_{0.4}S/ZnS) | | | | | |

Referring to FIG. 8 and Table 2, the quantum dots of Comparative Test Example 1 consisting of only a AgIn_{0.5}Ga_{0.5}S core had a narrow FWHM of 36 nm, but had a low quantum yield of 60% and a very low quantum yield retention rate of 14 w %. In the quantum dots of Comparative Test Example 2 in which a ZnS shell was formed on a AgIn_{0.5}Ga_{0.5}S core, a quantum yield and a quantum yield retention were 81% and 78%, respectively, which was considerably improved as compared to Comparative Test Example 1, but a FWHM was 96 nm, which was widened to 2.5 times or more. That is, the quantum dots of Comparative Test Example 1 had a narrow FWHM of a PL spectrum but had an insufficient quantum yield and quantum yield retention rate, and the quantum dots of Comparative Test Example 2 had an improved quantum yield and quantum yield retention rate but had a considerably increased FWHM, resulting in degradation in color reproducibility.

Referring to FIG. 9 and Table 2, the quantum dots of Comparative Test Example 3, Test Example 1, and Test Example 2 all included a CuInₓGa₁₋ₓS shell with a different composition between a AgIn_{0.5}Ga_{0.5}S core and a ZnS shell, and a quantum yield and a quantum yield retention rate were improved as compared to Comparative Test Example 1, and a FWHM was narrowed as compared to Comparative Test Example 2. Here, all of the FWHM, the quantum yield, and the quantum yield retention rate of the quantum dots of Test Example 1 and Test Example 2 are superior as compared to the quantum dots of Comparative Test Example 3. This is believed to be due to the fact that band gap energy of a shell of the quantum dots of Test Examples 1 and 2 is less than band gap energy of a core thereof.

Referring to FIG. 10, the quantum yield retention rate of the quantum dots of Comparative Test Example 1 is shown to rapidly decreasing according to a light exposure time, and a degree of decrease in quantum yield retention rate according to a light exposure time is shown to being gradually improved in the order of Comparative Test Example 2, Comparative Test Example 3, Test Example 1, and Test Example 2.

Table 3 is a table showing a maximum PL wavelength, a FWHM, a quantum yield, and a quantum yield retention rate after exposure to light for 2 hours of Comparative Test Examples 4 to 6, Test Example 3, and Test Example 4.

TABLE 3

| | Band gap | | | | |
|---|---|---|---|---|---|
| | energy | | | | Quantum |
| | difference | Maximum | | | yield |
| | between core | PL | FWHM | Quantum | retention |
| | and shell (eV) | wavelength | (nm) | yield (%) | rate (%) |
| Comparative Test Example 4 | — | 624 | 42 | 60 | 17 |
| (AgIn_{0.9}Ga_{0.1}S) | | | | | |
| Comparative Test Example 5 | — | 611 | 102 | 84 | 84 |
| (AgIn_{0.9}Ga_{0.1}S/ZnS) | | | | | |
| Comparative Test Example 6 | −0.22 | 617 | 59 | 85 | 87 |
| (AgIn_{0.9}Ga_{0.1}S/CuIn_{0.3}Ga_{0.7}S/ZnS) | | | | | |
| Test Example 3 | +0.08 | 630 | 57 | 92 | 94 |
| (AgIn_{0.9}Ga_{0.1}S/CuIn_{0.6}Ga_{0.4}S/ZnS) | | | | | |
| Test Example 4 | +0.28 | 641 | 56 | 93 | 96 |
| (AgIn_{0.9}Ga_{0.1}S/CuIn_{0.8}Ga_{0.2}S/ZnS) | | | | | |

Referring to Table 3, the quantum dots of Comparative Test Example 4 consisting of only a AgIn_{0.9}Ga_{0.1}S core had a narrow FWHM of 42 nm, but had a low quantum yield of 60% and a very low quantum yield retention rate of 17 w %. In the quantum dots of Comparative Test Example 5 in which a ZnS shell was formed on a AgIn_{0.9}Ga_{0.1}S core, each of a quantum yield and a quantum yield retention was 84%, which was considerably improved as compared to Comparative Test Example 4, but a FWHM was 102 nm, which was widened to 2.4 times. That is, the quantum dots of Comparative Test Example 4 had a narrow FWHM of a PL spectrum but had an insufficient quantum yield and quantum yield retention rate, and the quantum dots of Comparative Test Example 5 had an improved quantum yield and quantum yield retention rate but had a considerably increased FWHM, resulting in degradation in color reproducibility.

Referring again to Table 3, the quantum dots of Comparative Test Example 6, Test Example 3, and Test Example 4 all included a CuInₓGa₁₋ₓS shell with a different composition between a AgIn_{0.9}Ga_{0.1}S core and a ZnS shell, and a quantum yield and a quantum yield retention rate were improved as compared to Comparative Test Example 4, and a FWHM was narrowed as compared to Comparative Test Example 5. Here, all of the FWHM, the quantum yield, and the quantum yield retention rate of the quantum dots of Test Example 3 and Test Example 4 are superior as compared to the quantum dots of Comparative Test Example 6. This is believed to be due to the fact that band gap energy of a shell of the quantum dots of Test Examples 3 and 4 is less than band gap energy of a core thereof.

Since a quantum dot according to the disclosure includes a first shell having band gap energy that is less than band gap energy of a core, the characteristics of a narrow FWHM and excellent quantum efficiency may be exhibited, and the quantum dot may be used to provide an optical member and an electronic apparatus which have high quality.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A quantum dot comprising:
a core comprising a Group I element, a Group III element, a Group VI element, and gallium (Ga);
a first shell covering the core, the first shell comprising a Group I element, a Group III element, a Group VI element, and gallium (Ga); and
a second shell covering the first shell, wherein
band gap energies of the core, the first shell, and the second shell satisfy Expressions 1 and 2: 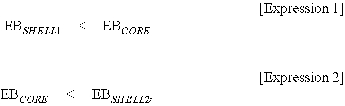
wherein in Expressions 1 and 2,
EB_{CORE} is a band gap energy of the core,
EB_{SHELL1} is a band gap energy of the first shell, and
EB_{SHELL2} is a band gap energy of the second shell.

2. The quantum dot of claim 1, wherein the Group I element of the core and the Group I element of the first shell are each independently copper (Cu), silver (Ag), gold (Au), or a combination thereof.

3. The quantum dot of claim 1, wherein the Group I element of the core is different from the Group I element of the first shell.

4. The quantum dot of claim 1, wherein the Group III element of the core and the Group III element of the first shell are each independently aluminum (Al), indium (In), thallium (Tl), or a combination thereof.

5. The quantum dot of claim 1, wherein the Group VI element of the core and the Group VI element of the first shell are each independently sulfur (S), selenium (Se), tellurium (Te), or a combination thereof.

6. The quantum dot of claim 1, wherein the core comprises at least one of Ag, In, Ga, and S.

7. The quantum dot of claim 1, wherein the first shell comprises at least one of Cu, In, Ga, and S.

8. The quantum dot of claim 1, wherein
the core has a composition of AgInₓGa₁₋ₓS, provided that 0<x<1, and
the first shell has a composition of CuIn_{y}Ga_{1-y}S, provided that 0<y<1.

9. The quantum dot of claim 8, wherein the quantum dot satisfies one of Conditions 1 to 7:
[Condition 1]
when the core has a composition of AgInₓGa₁₋ₓS, provided that 0<x≤0.2, the first shell has a composition of CuIn_{y}Ga_{1-y}S, provided that 0<y<1;
[Condition 2]
when the core has a composition of AgInₓGa₁₋ₓS, provided that 0.2<x≤0.3, the first shell has a composition of CuIn_{y}Ga_{1-y}S, provided that 0.1≤y<1;
[Condition 3]
when the core has a composition of AgInₓGa₁₋ₓS, provided that 0.3<x≤0.4, the first shell has a composition of CuIn_{y}Ga_{1-y}S, provided that 0.2≤y<1;
[Condition 4]
when the core has a composition of AgInₓGa₁₋ₓS, provided that 0.4<x≤0.6, the first shell has a composition of CuIn_{y}Ga_{1-y}S, provided that 0.3≤y<1;
[Condition 5]
when the core has a composition of AgInₓGa₁₋ₓS, provided that 0.6<x≤0.7, the first shell has a composition of CuIn_{y}Ga_{1-y}S, provided that 0.4≤y<1;
[Condition 6]
when the core has a composition of AgInₓGa₁₋ₓS, provided that 0.7<x≤0.8, the first shell has a composition of CuIn_{y}Ga_{1-y}S, provided that 0.5≤y<1; or
[Condition 7]
when the core has a composition of AgInₓGa₁₋ₓS, provided that 0.8<x≤1, the first shell has a composition of CuIn_{y}Ga_{1-y}S, provided that 0.6≤y<1.

10. The quantum dot of claim 1, wherein the second shell comprises a Group II-VI compound, a Group III-VI compound, or a combination thereof.

11. The quantum dot of claim 1, wherein the second shell comprises ZnS, ZnSe, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

12. The quantum dot of claim 1, wherein a full width at half maximum of a photoluminescence (PL) spectrum of the quantum dot is less than or equal to about 60 nm for incident light having a wavelength of 450 nm.

13. The quantum dot of claim 1, wherein a diameter of the core is in a range of about 2 nm to about 8 nm.

14. The quantum dot of claim 1, wherein
a thickness of the first shell is in a range of about 1 nm to about 2 nm, and
a thickness of the second shell is in a range of about 0.3 nm to about 2 nm.

15. The quantum dot of claim 1, wherein a surface of the quantum dot comprises an organic ligand or a metal halide.

16. An optical member comprising:
the quantum dot of claim 1.

17. An electronic apparatus comprising:
the quantum dot of claim 1.

18. The electronic apparatus of claim 17, further comprising:
a light source; and
a color conversion member disposed on a path of light emitted from the light source, wherein
the color conversion member comprises the quantum dot.

19. An electronic equipment comprising:
the electronic apparatus of claim 17.

20. The electronic equipment of claim 19, wherein the electronic equipment is a flat panel display, a curved display, a computer monitor, a medical monitor, a television, a billboard, an indoor light, an outdoor light, a signaling light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro-display, a three-dimensional (3D) display, a virtual or augmented reality display, a vehicle, a video wall with multiple displays tiled together, a theater screen, a stadium screen, a phototherapy device, or a signboard.
